(19) United States
(12) Patent Application Publication
(10) Pub. No.: US 2003/0044539 A1
(43) Pub. Date: Mar. 6, 2003

(54) Process for producing photovoltaic devices

(76) Inventor: Robert S. Oswald, Williamsburg, VA (US)

Correspondence Address: BP America Inc., Docket Clerk, Law Department, M.C. 2207A, 200 East Randolph Drive, Chicago, IL, 60601-7125, US

(21) Appl. No.: 10/214,227

(22) Filed: Aug. 7, 2002

Related U.S. Application Data
(63) Continuation-in-part of application No. 10/068,733, filed on Feb. 6, 2002.
(60) Provisional application No. 60/266,771, filed on Feb. 6, 2001.

(51) Int. Cl. B05D 1/36; B05D 5/12; B05D 3/00; C23C 16/00

(52) U.S. Cl. 427/404; 427/58; 427/555; 118/718; 118/719

(57) ABSTRACT

A continuous process for depositing a thin film layer or layers on a substrate during the production of thin film photovoltaic devices comprising moving the substrate at an elevated temperature in a reduced pressure environment past one or more sources of material to be deposited thereby forming on the substrate at least one thin film of the material from the source.

### BACKGROUND OF THE INVENTION

This application is a continuation-in-part application of U.S. patent application Ser. No. 10/068,733, filed on Feb. 6, 2002.

This invention relates to photovoltaic devices, particularly photovoltaic devices comprising thin films of semiconductor materials, such as thin films of amorphous silicon. More particularly, this invention relates to thin film photovoltaic devices comprising amorphous silicon and produced by a continuous or semi-continuous process that provides for the rapid production of such photovoltaic devices in a variety of dimensions useful for architectural applications such as, for example, windows, building facades and roofs, canopies, awnings and other applications.

It would be very desirable to be able to manufacture photovoltaic devices such that the devices could be used as a readily available, low cost building material. If such photovoltaic devices were available architects and builders would more readily incorporate the photovoltaic devices into the construction of a building. The building facade or roof, for example, could then function as a source of renewable electrical power to be used in the operation of the building or for connection to the local grid for use by other electric power consumers. In order to be able to supply photovoltaic devices into this market, the photovoltaic device would need to be made of a versatile material, such as glass, that can also serve as a durable and aesthetically appealing building medium, and in a variety of dimensions to meet the variable needs of architects and builders.

A variety of photovoltaic devices are available commercially. One group of photovoltaic devices is based on crystalline or polycrystalline silicon semiconductor materials. These devices which comprise doped wafers of crystalline or polycrystalline silicon are highly efficient in converting light energy into electrical energy, but since they have as their central feature crystalline or polycrystalline wafers, they are not readily amenable to manufacturing the designs and configurations most desirable for building facades.

Another group of photovoltaic devices available commercially are based on thin film semiconductor materials. Thin film photovoltaic devices may be constructed of amorphous silicon-containing semiconductor films on a substrate. The substrate of the thin film photovoltaic device can be made of glass or a metal, such as aluminum, steel or other metal. Soda-lime glass has been often used as a substrate because it is inexpensive, durable and transparent. If a glass substrate is used, a transparent conductive coating, such as tin oxide (SnO₂) can be applied to the glass substrate prior to forming the amorphous silicon-containing semiconductor films. A metallic contact can be formed on the back of the semiconductor films. Such photovoltaic devices can be made semitransparent by removing a portion of the back metal contact by, for example, laser scribing. The semitransparent photovoltaic panel or array can then be used a window or even as a roof if a degree of transparency is desired.

The thin film, amorphous silicon-type of photovoltaic devices are excellent candidates for the high volume, economically and aesthetically appealing photovoltaic devices that can be used in architectural applications meeting many of the criteria mentioned above. However, to date, processes for manufacturing thin film photovoltaic devices on glass substrates have been directed to batch-type processes wherein the slow steps in the batch-mode process are the steps of forming the amorphous, semiconductor layers on the glass substrates. Additionally, the vacuum deposition chambers used to apply the amorphous silicon layers to the glass substrates in these batch-mode processes are designed to accommodate only one size piece of glass substrate which is not of a size that would be suitable for all architectural uses. Additionally, because it is a batch-mode type of operation, the ability to mass-produce amorphous, thin-film photovoltaics at lower cost is hampered.

The art, therefore, needs a method of producing thin film photovoltaic devices in a continuous or at least semi-continuous manner where the dimensions of the photovoltaic device can be varied to meet the demands of varied architectural applications, and where the photovoltaic devices can be produced at a cost that will make them highly attractive building materials serving the dual purpose of providing a construction material and a source of renewable electrical power. The present invention provides such a process as well as the apparatus to perform such a process. The present invention also provides new photovoltaic devices that can be manufactured by such processes.

### SUMMARY OF THE INVENTION

A continuous process for depositing a thin film layer or layers on a substrate during the production of thin film semiconductor devices such as thin film photovoltaic devices comprising depositing at least one thin film layer on a substrate using one or more sources of layer material to be deposited, whereby the substrate and a means for depositing the material move in opposite relation to each other thereby forming on the substrate at least one thin film layer of the material.

This invention is also a semiconductor layer made by depositing on a substrate at an elevated temperature and in a reduced pressure environment one or more semiconductor materials whereby the substrate and the means for depositing one or more semiconductor materials on the substrate move in opposite relation to each other thereby forming on the substrate at least one layer of semiconductor material. The semiconductor layers of this invention are useful for manufacturing photovoltaic devices. This invention is also an apparatus for making the semiconductor layers of this invention.

### BRIEF DESCRIPTION OF THE DRAWING

FIG. 1 is a cross-sectional view of a monolithic single-junction photovoltaic device that can be made by the present invention.

FIG. 2 is a cross-sectional view of a monolithic tandem junction photovoltaic device that can be made by the present invention.

FIG. 3 is a process flow diagram for producing photovoltaic devices in accordance with principles of the present invention.

FIGS. 4A and 4B combined is a schematic view of an apparatus for the deposition of thin film semiconductor layers in accordance with the present invention.

FIG. 5 is a perspective view of a photovoltaic module that can be made by the process of this invention.

FIGS. 6A and 6B are schematic diagrams of laser scanning apparatus useful in the process of this invention.

FIG. 7 is a schematic diagram of a laser scanning apparatus useful in the process of this invention.

FIG. 8 is a schematic diagram of a laser scanning apparatus useful in the process of this invention.

FIG. 9 is a schematic diagram of a laser scanning apparatus useful in the process of this invention.

FIG. 10 is a graph showing the relative oxygen concentration as a function of depth in an amorphous silicon layer of this invention.

### DETAILED DESCRIPTION OF THE INVENTION

This invention is a process useful for the production of thin film photovoltaic devices that can, for example, be used in architectural applications such as in building facades, roofs, and in canopies, shades, awnings, and the like. While this invention is not limited to a specific type of thin film photovoltaic device, this invention is particularly suited to the production of thin film photovoltaic devices containing at least one amorphous silicon-containing semiconductor layer, especially an amorphous hydrogenated silicon (a-Si:H) layer. Generally, the thin film photovoltaic device comprises a substrate, preferably a transparent vitreous substrate, an electrically conductive contact on the substrate, one or more semiconductor layers which generate an electric charge separation upon exposure to light, and a second electrically conductive contact. The semiconductor layer or layers are positioned between the electrically conductive contacts. The semiconductor layers are deposited in a manner that provides for a junction and preferably the photovoltaic devices of this invention contain at least one p,i,n or “p-i-n” junction, or at least one n,i,p or “n-i-p” junction although other types of semiconductor junctions can be utilized. The p-i-n junction can exist in a semiconductor comprising p-, i- and n-regions or layers. The i-region is an intrinsic region, the p-region is typically a positively doped region, and the n-region is typically a negatively doped region.

The i-region is positioned between the p- and n-regions in the p-i-n junction or the n-i-p junction. It is generally understood that when light, for example, solar radiation, impinges on a photoelectric device containing a p-i-n or n-i-p junction, electron-hole pairs are generated in the i-region. The “holes” from the generated pair flow toward the n-region and the electrons from the generated pair flow toward the p-region. The contacts are generally directly or indirectly in contact with the p- and n-regions or layers. Current will flow through an external circuit connecting these contacts as long as light continues to impinge on the photoelectric device thereby generating the electron-hole pairs.

In the process of this invention the substrate used to form the photovoltaic devices of this invention can be any suitable substrate for receiving the electrically conductive contact and semiconductor layers of the photovoltaic device. The substrate is generally flat and can be glass, such and soda-lime glass or a low iron glass, a plastic such as a polyimide, or a metal film such as aluminum, steel, titanium, chromium, iron, and the like. Glass, particularly a highly transparent or transmissive glass is preferred. As will be discussed in greater detail herein below, a low iron glass is the preferred substrate. The substrate can be in any size and shape provided it can fit into the processing equipment used in the process of this invention. If larger substrate sizes are desired, the processing equipment as described herein will need to be sized accordingly. Generally, however, for most architectural applications, the substrate will be made of glass and will range in size from about 10 square feet to about 200 square feet and will preferably be either rectangular or square in shape, although the exact shape is not limited. One of the features of the process of this invention is the ability to process a range or variety of substrate shapes and sizes without changing the processing apparatus. Thus, the process of this invention can be used to manufacture photovoltaic devices suitable, for example, for specific architectural application. The thickness of the substrate is also variable and will, in general, be selected in view of the application of the photovoltaic device. If, for example, the photovoltaic device uses glass as the substrate, the thickness of the glass can range in thickness from 0.088 inches to about 0.500 inches, more preferably from about 0.125 inches to about 0.250 inches. If the glass will be used in large dimensions, such as for example, at least about 60, or at least about 200 square feet, the glass will preferably have a thickness of at least about 0.125 inches, more preferably of at least about 0.187 inches. When the glass substrate has a thickness of at least about 0.187 inches or at least about 0.250 inches, it will preferably be a low iron glass. By low iron we mean, preferably, that the glass has no more than about 0.1 wt % iron, more preferably less than about 0.1 wt % iron, measured as elemental iron.

As set forth above, the process of this invention is a continuous or at least a semi-continuous process for preparing thin film photovoltaic devices. By continuous, we mean a process whereby the substrate moves continuously along on a belt, on rollers, jig, moving framework, or other means for conveying the substrate from one operation or step in the process to the next operation or step. The means for conveying the substrate can comprise two or more different ways of conveying the substrate. The substrate can move horizontally or vertically, or nearly vertically (e.g. ±10° from vertical) through the process.

It is preferable that the process of this invention be completely continuous in that the means for conveying the substrate conveys the substrate to and through each step or individual operation in the overall process. However, it is not necessary for the process of this invention to be completely continuous. One or more steps can be completed in a manner isolated from the rest of the processes or in what is many times referred to as a batch-type of process step. When one or more (but not all) process steps are conducted so that it is isolated from the rest of the process steps, the overall process is referred to herein as a semi-continuous process.

An embodiment of the process of this invention will now be described utilizing glass as the substrate material. However, it is to be understood that the invention is not so limited, and any of the above mentioned or other suitable substrates can be used.

In this embodiment using glass as the substrate, the glass, preferably flat glass, and preferably low iron glass, is obtained from a glass vendor. Preferably the glass is supplied in the desired size and shape, heat treated with the edges seamed to enhance the strength of the glass. However, optionally, the glass can be supplied without such treatment and the first steps of the process of this invention would be to prepare the glass by cutting it to the desired shape, seam the edges to provide for crack resistance and to heat strengthen the glass. Heat strengthening can take place either before or after the cutting and before or after the seaming procedure. Preferably the heat strengthening is conducted after the cutting and the seaming of the glass. Another step in the process is to apply a conductive strip or strips, also called bus bars, which function as electrical conduits or wires from the photovoltaically active portions of the photovoltaic device to, preferably, a central location on the substrate, so the photovoltaic device can be connected to the device or system using the electric current generated by the photovoltaic device. The connection is suitably made by soldering an external wire or applying an electrical connector to the ends of conductive strips or bus bars. Such conductive strips can be a wire in any shape such as for example a flat tape and can be made of any material that is electrically conductive, durable and can withstand the further processing conditions of the process of this invention if the conductive strips are added to the substrate as one of the initial steps in the process. Such means for conducting electrical current is preferably firmly bound or bonded to the substrate so that it does not separate during later processing steps or when the photovoltaic device is in service. Highly suitable conductive strips can be added to the substrate as a commercially available fritted conductive paste comprising a fritted metal such as silver, copper, tin, nickel, antimony or combinations of one or more thereof. The paste also typically comprises an organic solvent that will evaporate when heated and one or more organic binders which will burn or evaporate when the paste is heated to a sufficiently high temperature. The fritted paste can be deposited on the glass substrate in a desired pattern by a suitable paste-dispensing machine. The paste can be applied to the substrate in the desired width so that when the substrate containing the paste is heated to the proper temperature to evaporate the solvent and burn or evaporate the organic binder, a durable conductive strip is formed. Thus, in the process of this invention the conductive strip is preferably applied to the substrate, preferably while the substrate is moving, by depositing on the glass substrate a fritted conductive paste using, for example, a paste dispenser or other means for depositing a paste material in the desired pattern and subsequently heating or curing the paste in a furnace or oven at an elevated temperature such as for example about 50° C. to about 600° C., more preferably about 100° C. to about 500° C., and for a time sufficient to cure the paste and form a conductive strip means. This heating step can also be done during the glass strengthening process. If the material used to form the bus bars can be cured at a lower temperature, for example at a temperature of about 250° C. or lower, the curing of the bus bar material can be reserved until the final stages of the process and, for example, can be combined with an annealing step where the back or rear contact of the module is cured by heating. U.S. Pat. No. 5,593,901, which is incorporated herein in its entirety, describes suitable conductive pastes and methods for adding them to a substrate to form bus bars and conductive strips useful in the process and photovoltaic devices of this invention.

The invented process comprises applying a front contact to the substrate. Optionally, the substrate is washed and dried before the front contact is applied. Washing is accomplished using deionized water with or without a detergent or other surfactant contained therein as a washing medium, for example, applied as a high power spray, or by submerging the substrate in a bath of the washing medium and optionally applying agitation to the bath or some other means for inducing a washing or cleaning of the substrate. Ultrasonic cleaning is also suitable. The substrate is preferably rinsed with deionized water to remove the cleaning medium and then dried by a means for drying the substrate such as for example hot air, blowing with air, or other means for drying the substrate.

The front contact comprises one or more layers of a suitable transparent conductive material. Typically, the front contact comprises one or more transparent, preferably doped conductive oxides (CTO or TCO) such as tin oxide, indium-tin oxide, zinc oxide, or cadmium stannate. The dopant can, for example be fluorine, aluminum or boron and the like. In the process of this invention, the preferred front contact comprises doped zinc oxide. When the front contact is zinc oxide, the dopant is preferably aluminum and is present in the zinc oxide at a level of about 0.5 to about 4 weight percent. Prior to depositing the front contact on the substrate, silicon dioxide or other transparent dielectric substance can be deposited on the substrate. The dielectric substance, if applied, is generally deposited in a layer about 100 to about 2,000 Å thick, more preferably about 500 to about 1000 Å. The dielectric substance can, for example, be applied by physical vapor deposition (PVD) such as if sputtering or reactive sputtering or by low-pressure chemical vapor depositions.

The front contact preferably comprising a CTO and most preferably zinc oxide is deposited to a thickness that provides for a durable and effective front contact. Typically, it is deposited to a thickness of about 4,000 to about 12,000 Å, more preferably about 800 to about 10,000 Å. The front contact is suitably deposited by one or more sources or methods such as chemical vapor deposition (CVD), low pressure chemical vapor deposition (LPCVD), PVD or by one or more sputtering techniques such a sputtering a metal oxide target or a metal target in an oxygen atmosphere. LPCVD of, for example, zinc oxide can be accomplished by directing at the substrate a mixture of a reactive zinc compound such as a dialkyl zinc, for example, diethyl zinc, and water, optionally in the presence of a dopant such as diborane. The reactive zinc compound reacts with the water to form zinc oxide in situ and is deposited on the substrate. Combining LPCVD and PVD can be used to optimize the morphology for the zinc oxide or other CTO. The morphology of the CTO layer is preferably a textured morphology. By textured, it is meant, preferably, that the CTO layer has surface features greater than about 0.2 micrometers in size. Preferably, the morphology of the CTO layer is such that it has a scattered transmission of more than about 1 percent, preferably up to about 30 percent, or up to about 10 or 20 percent using 700 nm wavelength light. Scattered transmission means the percentage of light energy incident on the substrate coated with the textured CTO that is transmitted through the substrate at all non-incident angles. Such textured surface improves the efficiency of the photovoltaic device containing such textured surface. Suitable texturing can be achieved by using an acid etch process such as by exposing the CTO layer to a dilute aqueous solution of hydrofluoric acid at a concentration of about 0.1 to about 1 weight percent acid, for about 15 to about 20 seconds, at about room temperature followed by a thorough rinsing with water to remove residual acid. Another suitable method for the texturing of a CTO layer, such as a tin oxide CTO layer, is set forth in U.S. Pat. No. 5,102,721 which is incorporated herein by reference. However, in the preferred process of this invention the texturing of the CTO layer such as zinc oxide is accomplished by reactive ion etching. In reactive ion etching carbon tetrafluoride, oxygen or like compound or element is used to form a reactive plasma atmosphere to plasma etch the CTO layer such as zinc oxide to achieve the desired morphology of the layer, such as the textured morphology as described above. During the plasma etch in the process of this invention, the plasma reacts with the CTO material to etch the CTO layer. The product or by-products are volatilized and pumped out or exhausted from the etching chamber by vacuum pumps. As will be discussed in greater detail below, in the preferred process of this invention the deposition of the first contact is conducted in a continuous manner as the substrate and source of material deposited move in opposite relation to each other. Preferably, the substrate moves under a stationary source or sources of the front contact material. The deposition is suitably conducted at a deposition rate of about 0.5 Å per second to about 1,000 Å per second layer thickness, more preferably at a rate of about 1 Å per second to about 500 Å per second when the substrate is moving by the source or sources of front contact material. Preferably the substrate is moving by the source or sources of front contact material at a rate of about 0.1 meter per minute to about 4 meters per minute, more preferably about 1 meter per minute to about 2 meters per minute and, preferably, such deposition rates are achieved while the substrate is moving at these rates. It is preferable to deposit the front contact layer, preferably zinc oxide, on the substrate at a temperature of about 100° C. to about 450° C., more preferably about 150° C. to about 250° C., and at a pressure of about 0.5 milliTorr to about 4 Torr, more preferably about 2 milliTorr to about 2.5 Torr. It is to be understood that in the preferred process of this invention all the source or sources of material being deposited are stationary and the substrate material moves past the source. However, the invented process is not so limited. The source may also be moved past a stationary substrate or both the substrate and the source of material being deposited may be moving in order to achieve a movement of the substrate and source or sources of material being deposited in opposite relation to each other. Prior to depositing the front contact at these pressures and at these temperatures, it is preferable to heat the substrate at atmospheric pressure to the desired process temperature as mentioned above before the substrate enters the low pressure chamber for the deposition of the front contact. Due to the low pressure of the deposition chamber, it would be more difficult to increase the temperature of the substrate to the desired deposition temperature while in the low pressure chamber. For example, some sort of radiative heating would be required. Whereas, if an ordinary oven is used at atmospheric pressure prior to the substrate entering the low pressure deposition chamber, heating to the desired temperature is efficient and rapid. As will be discussed in more detail herein below, it is advantageous in the process of this invention to deposit each of the front contact, the semiconductor layer or layers and the first layer of the rear contact at relatively similar temperatures (e.g. ±20° C.) and pressures (e.g. ±5 Torr). In this manner the temperature of the substrate need not be altered, at least not to a great extent, between process steps thereby providing for a rapidly operating continuous process. Also, if the pressures are relatively similar for each such process step, the operations of front contact deposition, semiconductor deposition, and the rear contact deposition can take place in a continuous operation without the time consuming need to make major changes in temperature or pressure. For example, if the operation of depositing the front contact, semiconductor layers and the rear contact are conducted at relatively the same temperatures and pressures, these process steps can take place in a production apparatus that is connected such that a substrate on which the deposition is taking place can move through the apparatus in a continuous manner wherein the front contact, semiconductor layers, and the rear contact are deposited in a continuous, sequential and rapid manner without appreciable delay between the deposition steps. The front contact, preferably a CTO, and more preferably zinc oxide, is preferably textured as described above. As described above, most preferably, the texturing or morphology is such that it improves the light scattering of the front contact. Preferably, the front contact has a scattered transmission using 700 nanometer light of at least about 75%, more preferably at least about 80%, and most preferably at least about 85%. As described above, the texturing or morphology can be provided during the deposition process or can be accomplished after the deposition for example by one or more etching techniques such as etching by reactive ion etching or by acid immersion. The front contact is divided or patterned to provide for a collection of individual photovoltaic cells of the photovoltaic module. A photovoltaic module is a collection of individual cells connected, typically, in series to achieve the desired voltage for the module. The dividing of the front contact is preferably accomplished by removing strips of the deposited front contact. For example, these strips or scribes can be about 30 micrometers to about 150 micrometers wide, preferably from about 40 micrometers to about 80 micrometers wide and suitably spaced about 0.5 cm to about 2.5 cm, more preferably about 0.8 cm to about 1.2 cm from each other. The spacing of these strips will determine the width of the individual cells on the photovoltaic module. Typically, the strips of removed front contact run from near one edge of the substrate to the opposite edge, for example, from about 0.5 cm to about 2.0 cm from the edge of the substrate. The, strips, however, can extend to the edge of the substrate. The strips are typically parallel to one another, are typically straight, and typically parallel to the edge of the substrate. If the substrate is rectangular, these strips preferably run parallel to the longer edge of the substrate but can also run parallel to the shorter edge of the rectangular shaped substrate.

To form these strips in the front contact, the front contact material can be removed by any suitable method such as chemical etching, laser ablation or mechanical stylus. However, in the continuous or semi-continuous process of this invention the front contact material is preferably removed by laser scribing. In this method, one or more laser beams are directed at the substrate and scanned across the surface of the front contact material thereby removing the front contact material in the desired pattern.

The laser selected as well as the wavelength of the laser light, the pulse-width of the laser, the laser beam shape and the repetition rate are selected to efficiently remove the front contact in the region of the strips. For example, particularly when the front contact is the preferred zinc oxide, the laser is preferably an excimer, i.e., ArF, XeCl, XeF, KrF, ArCl, or a solid state Nd:YAG, Nd:YLF, or Nd:YVO₄ laser operating at a wavelength of about 190 nanometers to about 1,200 nanometers and suitably at a pulse-width of about 1 nanosecond to about 500 nanoseconds, more preferably of about 5 to about 100 nanoseconds, a repetition rate (reprate or pulse frequency) suitably of about 200 Hz to about 400 KHz more preferably about 1 KHz to about 200 KHz and most preferably at about 30 KHz to about 200 KHz. The reprate can, for example, be up to about 400 or 500 KHz or more. The laser beam shape is suitably top hat, delta function, or gaussian. Commercially available optics can be used to shape the laser beam to the desired shape. Preferably it is gaussian. It is preferable to scan the surface of the front contact to form the strips at rate that is about 0.1 meters/second to about 50 meters/second more preferably about 0.5 or 0.8 meters/second to about 20 meters/second. Scribe or scan rates of 1 or more, or 5 or more, or 10 or more meters/second can be used. At these scanning rates, the front contact can be removed to form the strips in a time period that is suitable for the continuous or semi-continuous processes of this invention.

In the preferred process of this invention, the laser scribing to form the strips or scribes in the front contact is conducted at the same or about the same temperature and at the same pressure or about the same pressure as the temperature and pressure used to deposit the front contact layer. Also, for this laser-scribing step, the laser mechanism is protected from the environment of the low pressure chamber where the laser scribing is taking place. Preferably the laser is operated from outside of the chamber whereby the laser light passes through, for example, a window in the chamber, the window preferably being made of quartz. In order to protect the window from being coated with the vaporized front contact material it is preferable to have a sweep gas pass over the surface of the window that is inside the chamber. Alternatively, a condenser is placed inside the chamber and near the window to preferentially condense the front contact material that is being removed during the scribing process before it reaches the window surface. In another embodiment, the window is repeatedly and rapidly changed by sliding or swinging another window in its place without substantial loss of vacuum. With this method, a partially obscured window can be removed, cleaned and replaced without interrupting the process.

The next step in the process is to apply an amorphous silicon-containing thin film semiconductor. The following will describe the application of a single junction semiconductor, however, the invention is not so limited. The amorphous silicon semiconductor comprises a p-i-n or a n-i-p amorphous silicon thin film layers with a bandgap suitably ranging from about 1.4 eV to 1.75 eV, usually 1.4 to 1.6 eV. As used herein, p-i-n means that the p-layer of the p-i-n junction is made first followed by the i- and then the n-layers. For a n-i-p junction, it is the n-layer that is made first followed by the i- then the p-layer. The amorphous silicon-containing thin film semiconductor can comprise hydrogenated amorphous silicon, hydrogenated amorphous silicon carbon or hydrogenated amorphous silicon germanium. For the formation of a p-i-n junction, the positively doped (p-doped) amorphous silicon p-layer of the amorphous silicon semiconductor is deposited on the CTO front contact. The p-layer can be positively doped with diborane (B₂ H₆), BF₃ or other boron-containing compounds. An amorphous silicon, undoped, active intrinsic i-layer can be deposited on the p-layer and a negatively doped (n-doped) amorphous silicon n-layer is deposited on the i-layer. The n-layer positioned on the i-layer can comprise amorphous silicon carbon or amorphous silicon negatively doped with phosphine (PH₃) or some other phosphorous-containing compound.

After the p-type layer has been formed to a thickness on the order of about 30 Å to about 250 Å, preferably less than 150 Å, the intrinsic layer is applied. The intrinsic layer is applied to a thickness suitably on the order of about 1,500 to about 10,000 Å, preferably about 2,500 to about 4,500 Å. After the intrinsic layer is applied an n-doped layer is applied. An n-type dopant, such as phosphine (PH₃), is added to, for example, a silane feed in order to form an n-type amorphous silicon layer suitably having a thickness of about 100 Å to about 400 Å, preferably less than 150 Å.

The amorphous silicon layer i-layer is suitably deposited at a deposition rate of about 1 Å per second to about 200 Å thickness per second, more preferably at a rate of about 2 Å per second to about 100 Å per second. During deposition the substrate and source or sources of amorphous silicon i-layer material being deposited move in opposite relation to each other. Preferably the substrate is moving by the source or sources of the silicon at a rate of about 0.1 meter per minute to about 4 meters per minute, more preferably about 1 meter per minute to about 2 meters per minute and, preferably such deposition rates are achieved while the substrate is moving past the source or sources of silicon at these rates. The amorphous silicon p- and n-layers are suitably deposited at a deposition rate of about 2 Å per second to about 50 Å thickness per second, more preferably at a rate of about 4 Å per second to about 10 Å per second. During deposition the substrate and source or sources of amorphous silicon p- and n-layer materials being deposited move in opposite relation to each other. Preferably, the source or sources of amorphous silicon are stationary and the substrate moves past the stationary source or sources of material being deposited. Preferably, the substrate is moving by the source or sources of the p- or n-doped silicon at a rate of about 0.1 meters per minute meter to about 4 meters per minute, more preferably about 1 meter per minute to about 2 meters per minute and, preferably, such deposition rates are achieved while the substrate is moving at these rates past the source or sources of p- or n-doped silicon. It is preferable to deposit the amorphous silicon layers at a temperature of about 50° C. to about 400° C., more preferably about 100° C. to about 300° C., and at a pressure of about 1 millitorr to about 5 Torr, more preferably about 4 milliTorr to about 2 Torr. The amorphous silicon layers are suitably deposited on the substrate by one or more sources or methods that can be used to continuously provide uniform layers of amorphous silicon on the substrate as it moves by the source. For example Plasma Enhanced Chemical Vapor Deposition (PECVD) and LPCVD can be used. Other methods or techniques for continuously depositing the amorphous layers include deposition using electron cyclotron resonant microwaves, hot wire CVD, cascaded arc plasmas, dc hollow cathode, tuned antenna microwaves, or rf hollow cathode. One or more sputtering techniques (PVD) can also be use to apply the amorphous semiconductor silicon layers having a p-i-n or n-i-p junction. Depending on the method used to deposit the amorphous layers different feeds can be used. For example, for the glow discharge type of methods, silane and silane/hydrogen mixtures can be used. With PVD, solid silicon along with an argon/hydrogen mixture can be used. For the hollow cathode technique, a silicon target and silane, or silane and hydrogen can be used.

The next step in the process is to remove strips of the amorphous silicon layers parallel to the strips formed in the front contact. However, prior to removing these strips, it is preferable to add a first layer of the back contact, preferably a transparent conductive oxide such as zinc oxide, tin oxide, or indium-tin oxide to the amorphous silicon layers. Preferably it is zinc oxide. This zinc oxide or other CTO layer such as indium-tin-oxide, cadmium stannate, or tin oxide is preferably applied to a thickness of about 600 Å to about 2,000 Å more preferably about 800 Å to about 1,400 Å. This zinc oxide or CTO layer is preferably applied at a deposition rate of about 10 Å per second to about 200 Å thickness per second, more preferably at a rate of about 20 Å per second, to about 100 Å per second thickness. During such deposition the substrate and source or sources of such CTO layer material being deposited move in opposite relation to each other. Preferably, the source or sources of CTO layers being deposited are stationary and the substrate moves past the stationary source or sources of material being deposited. Preferably the substrate is moving by the source or sources of oxide at a rate of about 0.1 meter per minute meter to about 4 meters per minute, more preferably about 1 meter per minute to about 2 meters per minute and, preferably, such deposition rates are achieved while the substrate is moving at these rates past the source or sources of oxide. The temperature of the deposition of the zinc oxide is suitably about 120° C. to about 250° C., preferably about 140° C. to about 200° C. and most preferably about 175° C. to about 195° C. The pressure for the deposition is suitably about 1 milliTorr to about 10 Torr, preferably about 2 milliTorr to about 3 Torr and most preferably about 4 milliTorr to about 2 Torr. The first layer of the back contact, if used, is suitably applied by reactively sputtered zinc or other metal in the presence of oxygen gas to form zinc or other metal oxide, preferably doped with aluminum or boron preferably using pulsed power supplies to ensure uniform cathode properties. Other methods for applying the first layer of the back contact can also be used such as LPCVD, AC sputtering or rf sputtering.

After the deposition of the first layer of the back contact, or if such a first layer is not deposited, the amorphous layer is treated to remove strips of the amorphous silicon layers. The amorphous silicon semiconductor material and first layer of back contact, if present, are removed in strips which are spaced from but generally parallel to the strips of conducive oxide removed from the first conductive layer. For example, these strips or scribes can be about 30 micrometers to about 150 micrometers wide, preferably from about 40 micrometers to about 80 micrometers wide and suitably spaced about 25 micrometers to about 150 micrometers, more preferably about 25 micrometers to about 100 micrometers from the strips removed from the front contact layer.

To form these strips or scribes in the amorphous layer, the amorphous layer can be removed by any suitable method such as laser ablation, chemical etching or mechanical scribing. However, in the continuous or semi-continuous process of this invention the strips of amorphous silicon semiconductor are suitably removed by laser scribing. In this method, one or more laser beams are directed at the amorphous silicon layer and scanned across its surface in the desired pattern thereby removing the amorphous silicon layers but not the conductive oxide of the front contact.

The laser selected as well as the wavelength of the laser light, the pulse-width of the laser, the laser beam shape and the repetition rate are selected to efficiently remove the amorphous silicon layer in the desired areas to form the strips or scribes. For example, the laser can be a Nd:YAG laser operating at a wavelength of about 532 nanometers. The laser can also be Nd:YLF or a Nd:YVO4-based laser. Both fundamental wavelength at 1064 nanometers and harmonic wavelengths at 532 nanometers and 355 nanometers can be used. Excimer lasers, for example, ArF, KrF, XeCl, and XeF lasers can also be used for forming the scribes in the semiconductor layer or layers. The laser used suitably has a pulse-width of about 1 nanosecond to about 500 nanoseconds, more preferably of about 5 nanosecond to about 100 nanoseconds, a repetition rate suitably of about 10 KHz to about 400 KHz, more preferably about 30 KHz to about 200 KHz. The reprate can be about 40 KHz or more, or 50 KHz or more, and can be up to about 300 KHz or more, or about 400 KHz or more. The beam shape is suitably gaussian, top hat, or delta function. Preferably it is gaussian. It is preferable to scan the amorphous layer at a rate that is about 0.1 meters/second to about 50 meters/second, more preferably about 0.8 meters/second to about 20 meters/second. Scan or scribe rates of 1 or more, or 5 or more, or 10 or more meters/second can also be used. At these scanning rates, the amorphous layer can be removed to form the strips or scribes in a time period that is suitable for the continuous or semi-continuous processes of this invention. Such scribes in the semiconductor layers can be discontinuous. That is, the scribe does not have to be continuous across all of its length. For example, it can be a series of spaced holes such as round or linear shaped holes separated by spaces where the semiconductor layer was not removed. In the process of this invention, the semiconductor layer can be removed by directing the laser beam or beams at the amorphous silicon semiconductor layer directly on top of or through transparent, such as glass, substrates, if such transparent substrates are used.

In the preferred process of this invention, the laser scribing to form the strips or scribes in the amorphous layers is conducted at the same or about the same temperature and at the same or about the same pressure as the temperature and pressure used to deposit the front contact layer. Also, the arrangement for the laser scribing in this step is the same as described for the laser scribing of the front contact whereby the laser and the laser controls are outside of the vacuum chamber containing the substrate being scribed. Similarly, as described for the front contact scribing step, the window through which the laser beam or beams enter the chamber needs to be protected, for example, by the same method as described for scribing the front contact, from having the material which is removed during the scribing from depositing on and obscuring the path of the laser beam.

The next step in the process is preferably the deposition of a metal rear or back contact. Generally, the rear contact is one or more highly conductive metals such as silver, molybdenum, platinum, steel, iron, niobium, titanium, chromium, bismuth, antimony, or, preferably, aluminum. The rear contact can be deposited by one or more methods for applying a thin film of metal such as PVD, LPCVD or evaporation. Preferably, however, the rear contact is applied using a magnetron sputtering technique, preferably from a rotatable magnetron source. The rear metal contact is applied to a thickness that is suitably about 1,000 Å to about 5,000 Å, preferably about 2,000 Å to about 3,000 Å, and most preferably about 2,000 Å to about 2,400 Å. The deposition of the rear metal contact is preferably done at a temperature of about 20° C. to about 250° C., more preferably about 50° C. to about 200° C. and most preferably at a temperature of about 100° C. to about 175° C. The pressure for the deposition of the rear metal contact is suitably about 0.2 milliTorr to about 10 milliTorr, preferably about 1 milliTorr to about 5 milliTorr. The rear metal contact is suitably applied at a rate of about 10 Å per second to 1,000 Å per second thickness, preferably at a rate of about 50 Å per second to about 500 Å per second and most preferably at a rate of about 100 Å per second to about 200 Å per second. During deposition the substrate and source or sources metal being deposited move in opposite relation to each other. Preferably, the source or sources of metal being deposited are stationary and the substrate moves past the stationary source or sources of metal being deposited. Preferably, the substrate is moving by the source or sources of the back metal contact at a rate of about 0.1 meter per minute to about 4 meter per minute, more preferably about 1 meter per minute to about 2 meters per minute and, preferably, such deposition rates are achieved while the substrate is moving at these rates past the source or sources of metal rear contact. The deposition of the metal rear contact provides for a preferably uniform metal coating or layer over the entire surface of the amorphous layers which, as described above, optionally have a CTO layer deposited thereon. When the metal rear contact is deposited it fills the strips or scribes in the amorphous layers thereby forming an electrical conduit or interconnect with the front contact. The back or rear metal contact can be annealed. Preferably, the annealing step is conducted at a temperature of about 120 to about 200° C. for about 10 to about 30 minutes. If such a heat annealing step is used it is preferably accomplished using an in-line infrared source in cylindrical configuration immediately after the metal deposition step and at the same pressure.

The next step in the process is to remove strips of the back metal contact to form the individual photovoltaic cells of the thin film photovoltaic device. The back contact layer is removed in strips or scribes which are spaced from but generally parallel to the strips or scribes in the amorphous semiconductor material. The strips of back contact metal can be about 30 micrometers to about 150 micrometers wide, preferably from about 40 micrometers to about 80 micrometers wide and suitably spaced about 25 micrometers to about 100 micrometers, preferably from about 40 micrometers to about 80 micrometers from the strips in the amorphous semiconductor layer. To form these strips in the back contact metal layer, the metal layer can be removed by any suitable means. However, in the continuous or semi-continuous process of this invention, the strips of the metal layer are suitably removed by laser scribing. In this method one or more laser beams are directed at the amorphous silicon layer passing through the front CTO layer, and scanned across the amorphous silicon layer in the desired pattern thereby removing the metal layers. In such a method, the laser beam ablates the amorphous silicon semiconductor and removes the metal next to it. The laser used to remove the desired sections of the back contact is preferably a continuous wave laser or more preferably a pulsed laser. The laser can be an ultraviolet laser such as an excimer laser, for example, an ArF (193 nm), KrF (248 nm), XeCl (308 nm), or XeF (351 nm) laser, and the like, or a third or forth harmonic of a Nd:YAG, Nd:YLF or Nd:YVO₄ laser. The laser can also be a visible or infrared laser. Most preferably, the laser used is a visible laser, preferably a green laser, for example, a frequency doubled Nd-YAG, Nd-YLF or Nd-YVO₄ laser. It is preferable to use a high repeating rate, high power laser, such as a Nd:YVO₄ laser. Preferably, the laser used operates at about 20-100 kHz at a rapid scribing speed of, for example, about 1-20 meters per second with a spot size of, for example, 0.1 to about 0.2 mm.

The laser used suitably has a pulse-width of about 10 nanoseconds to about 100 nanoseconds, more preferably about 10 to about 30 nanoseconds, a repetition rate suitably of about 1 kHz to about 200 kHz, more preferably about 10 to about 30 kHz. The repetition rate can be about 30 KHz or more, about 40 KHz or more, or about 50 KHz or more, and can be up to about 400 KHz or more or about 500 KHz or more. The beam shape is suitably gaussian, top hat, or delta function. For certain scribes gaussian beam shape may be disadvantageous because it tends to concentrate laser energy in the center of the spot. Therefore, a top hat laser profile is preferred because it generally provides for more uniform energy distribution within the laser spot. It is preferable to scan the amorphous layer a rate that is about 0.1 meters/second to about 50 meters/second, more preferably about 0.8 meters/second to about 20 meters/second to form the desired scribes in the back contact. Scribe rates of 1 or more, or 5 or more, or 10 or more meters/second can also be used. The grooves or scribes in the back contact metal preferably are about 10 micrometers to about 150 micrometers wide, preferably from about 40 micrometers to about 80 micrometers wide and are preferably parallel to and suitably spaced, suitably about 25 micrometers to about 100 micrometers, preferably from about 40 micrometers to about 80 micrometers from the strips or scribes in the amorphous silicon semiconductor layers.

The ablation of the semiconductor material to form the scribes or grooves in the metal contact layer is believed to produce particulates, for example, particulate silicon from the ablation of amorphous silicon, which structurally weaken and burst through the portions of metal film overlying the ablated semiconductor material to form the grooves or scribes that separate the metal film into a plurality of back electrodes. Such scribes are preferably substantially continuous. The exact laser parameters required to produce such continuous scribes in the metal film will, of course, depend on a number of factors, such as the thickness and material of the metal film, the characteristic wavelength of the laser selected, the power density of the laser, the pulse repetition rate and pulse duration of the laser, and the scribing feed rate. After the removal of the back contact, particularly after using the laser method, the photovoltaic cell is preferably cleaned, preferably using an ultrasonic bath. The cleaning process removes dust particles and melted materials along the edges of the scribe patterns thereby reducing shunting.

Methods for removing the back contact layer using a laser process are described in U.S. patent application Ser. No. 09/891/752 and PCT/US 01/20398 which are incorporated herein by reference in their entirety. In addition to disclosing the method of forming the laser scribes in the back contact, they also describe the dimensions of the laser scribes. They also describe a method for forming in the back contact a series of scribes that impart partial transparency to the photovoltaic device or imparting designs. Such laser scribing methods described therein can also be use in the continuous or semi-continuous process of this invention.

The process of this invention is preferably carried out in the continuous mode. In that mode, the substrate, preferably a flat glass substrate and preferably a low iron glass, is moved or carried along (the substrate positioned vertically, near vertically, or horizontally) a conveying system, for example rollers, through a series of deposition chambers where the various layers of the photovoltaic device as described above are deposited on the substrate. In order to enhance the speed of the process the substrate is moved through the different deposition steps at the same or about the same temperatures and preferably at the same or about the same pressures. For example, each deposition or laser scribing step is, in relation to its adjacent deposition or laser scribing step, at a temperature of ±2 to 25° C., or ±2 to 10° C., or ±1-5° C. and at a pressure of ±20 Torr or ±10 Torr or ±5 Torr compared to its adjacent deposition or scribing step. This is particularly preferable with respect to the deposition step for the CTO front contact layer, scribing of the front contact layer, deposition of the amorphous silicon layer, scribing of the amorphous silicon layer and, if used, second CTO layer for the back contact. In this manner it is not necessary to repeatedly cool and then reheat the substrate which would be time consuming and energy inefficient. In addition, in the continuous process of this invention the scribing steps to scribe the front contact and the amorphous layers, which are preferably accomplished by laser scribing, are also accomplished while the substrate and the conductive and semiconductor layer deposited thereon are at an elevated temperature and at the reduced pressures preferably used for the deposition procedures as described above.

For example, the zinc oxide deposition of the front contact, laser scribe of the front contact, deposition of the p, i and n amorphous silicon layers, laser scribe of the amorphous silicon layers, and zinc oxide deposition of the first layer of the back contact can occur at a temperature of about 180 to about 200° C. and at a pressure in the range of about 0.1 to about 2 Torr. The deposition of an aluminum back contact layer can occur at a temperature of about 150° C. but at a pressure of about 0.002 to 0.01 Torr. Thus, all the deposition steps and the laser scribing steps that take place between the deposition steps all occur at an elevated temperature within a certain range and all occur at a reduced pressure thereby eliminating the need for rapidly cooling or rapidly reheating the substrate.

In the process of this invention the chambers used to deposit the various layers of the photovoltaic device and the chambers used for the laser scribing steps at low pressure as described herein may be cylindrical in geometry, which provides strength for the low-pressure operations. A cylindrical geometry also provides for uniform heating of the substrates. Other geometries can be used, however. The temperature of the substrates during processing is preferably measured using noncontact infrared thermocouple arrays.

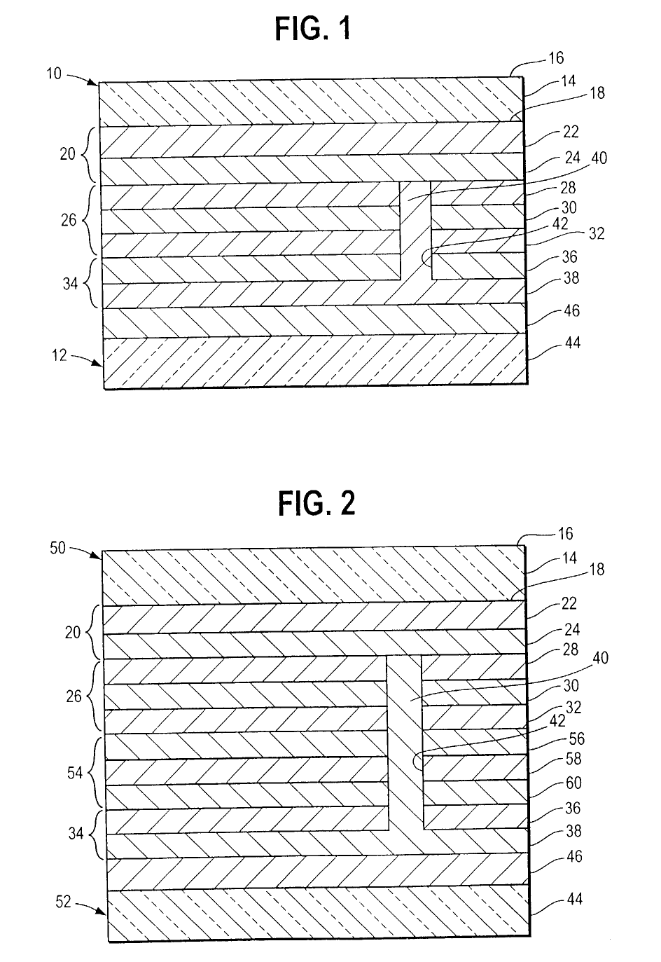

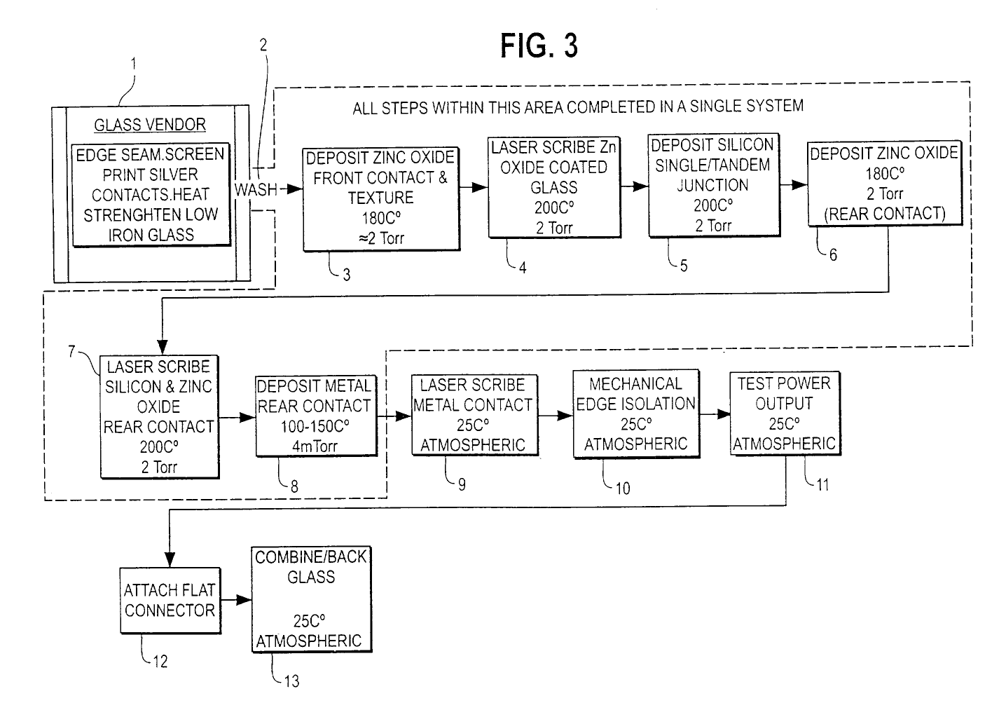

FIGS. 1 and 2 show in cross-sectional form, solar cells (photovoltaic devices) that can be made by this invention. FIG. 1 shows a single junction device and FIG. 2 shows a tandem junction device. The monolithic photovoltaic (PV) module 10 of FIG. 1 is a photovoltaic device which comprises a single junction solar cell 12. The solar cell has a generally flat substrate 14 made of transparent glass, which provides the front glass of the photovoltaic module. The substrate has an external outer (outside) surface 16 and an inwardly facing inner surface 18. The substrate comprises a low-iron glass.

A dual layer front contact 20 lies upon the substrate comprising an optional dielectric outer front layer 22 comprising silicon dioxide positioned upon the inner surface of the substrate and transparent zinc oxide inner back layer 24 positioned upon the optional dielectric layer.

An amorphous silicon-containing thin film semiconductor 26 (FIG. 1) provides a single junction solar cell. The amorphous silicon semiconductor solar cell comprises a p-i-n or a n-i-p amorphous silicon thin film semiconductor with a bandgap ranging from about 1.4 eV to 1.75 eV, usually to 1.6 eV. The amorphous silicon semiconductor or segment can comprise: hydrogenated amorphous silicon, hydrogenated amorphous silicon carbon or hydrogenated amorphous silicon germanium. The positively doped (p-doped) amorphous silicon p-layer 28 of the amorphous silicon semiconductor is deposited on the zinc oxide layer 24 of the front contact. The p-layer can be positively doped with diborane (B₂ H₆), BF₃ or other boron-containing compounds. An amorphous silicon, undoped, active intrinsic i-layer 30 is deposited upon the p-layer, and a negatively doped (n-doped) amorphous silicon n-layer 32 is deposited on the i-layer and can comprise amorphous silicon carbon or amorphous silicon negatively doped with phosphine (PH₃) or some other phosphorous-containing compound.

A dual layer rear contact (back contact) contact 34 is deposited upon the amorphous silicon n-layer of the solar cell 26. The inner metallic front layer 36 of the rear contact can comprise a transparent zinc oxide. The outer metallic rear (back) layer 38 of the rear contact can comprise a metal, such as silver or, preferably, aluminum.

An interconnect 40 provides an electrical contact between the zinc oxide layer of the front contact and the metal outer layer of the rear contact. The interconnect extends through a trench (hole) 42 in the amorphous silicon semiconductor layer and the zinc oxide inner layer of the rear contact.

A transparent superstrate 44 comprising glass can be positioned upon the back (rear) contact of the photovoltaic module and device. The photovoltaic module can be encapsulated with an encapsulating material (encapsulant) 46, such as ethylene vinyl acetate (EVA), to help seal and protect the photovoltaic module from the environment.

The monolithic module 50 of FIG. 2 provides a photovoltaic device, which comprises a tandem junction solar cell 52. The dual junction solar cell of FIG. 2 is generally structurally, physically and functionally similar to the single junction solar cell of FIG. 1, except as explained below. For ease of understanding, similar components and parts of the solar cells of FIGS. 1 and 2 have been given similar part numbers, such as substrate 14, front contact 20 with outer dielectric layer 22 and inner zinc oxide layer 24, amorphous silicon-containing thin film semiconductor 26 which provides front solar cell or segment, dual layer rear contact (back contact) 34 with a zinc oxide inner metallic layer 36 and an outer metallic layer 38, interconnect 40, trench 42, superstrate 44 EVA 46, etc. The p-i-n rear solar cell has p-, i-, and n-layers, which are arranged as previously explained. The p, i, and n-layers of the rear cell are sometimes referred to as the P₂-, i₂- and n₂-layers, respectively, of the rear cell. A rear (back) solar cell 54 comprising an amorphous silicon-containing thin film semiconductor is sandwiched and positioned between and operatively connected to the front cell and the rear (back) contact. The rear amorphous silicon cell can be similar to the front amorphous silicon cell described above. The amorphous silicon positively doped p₂-layer 56 of the rear cell is deposited on the amorphous silicon negatively doped n₁-layer 32 of the front cell. The amorphous silicon intrinsic i₂-layer 58 of the rear cell is between the n₂-layer 60 and p₂-layer 56 of the rear cell.

In multi-junction (multiple junction) solar cells, such as the tandem junction solar cells of FIG. 2, the i-layers of the amorphous silicon containing cells can comprise an active hydrogenated compound, such as amorphous silicon, amorphous silicon carbon or amorphous silicon germanium. The active p-layers of the amorphous silicon-containing cell can comprise a p-doped hydrogenated compound, such as p-doped amorphous silicon, p-doped amorphous silicon carbon or p-doped amorphous silicon germanium. The active n-layers of the amorphous silicon-containing cell can comprise an n-doped hydrogenated compound, such as n-doped amorphous silicon, n-doped amorphous silicon carbon or n-doped amorphous silicon germanium.

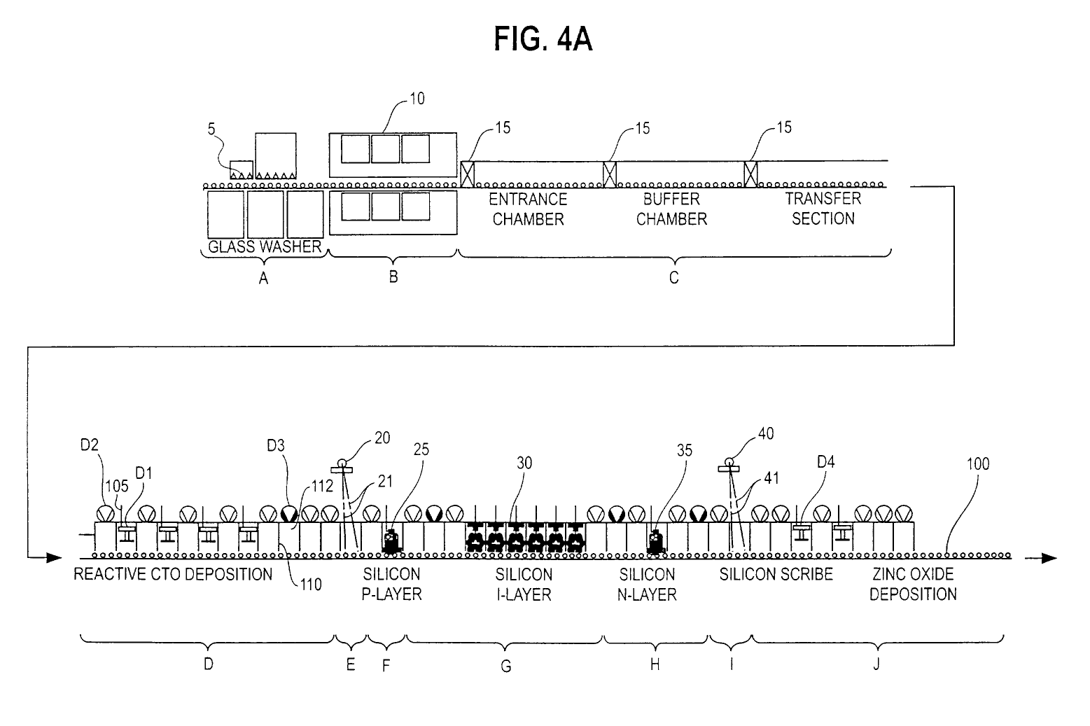

FIG. 3 shows in block diagram form a preferred embodiment of the continuous process of this invention.

In step 1 of FIG. 3 the glass in the selected size obtained from a vendor is edge seamed and a conductive frit paste applied for the electrical conduit or so called, “bus bars”. As described above, the bus bars are the electrical conduits that typically attach each end of the series connected cells in the module to an electrical connector for connecting the module to the system that will utilize the electric current generated by the module. Typically, the bus bars run along the length of the outer portion of the first and last cell in a module and lead to the connector. The glass, preferably a low-iron glass, is heated to about 600° C. to cure the frit and to heat strengthen the low-iron glass. In step 2 the glass is washed to remove debris. In step 3 the zinc oxide front contact is deposited and textured. The temperature for the deposition and texturing is about 180° C. and the pressure is about 2 Torr. Preferably the zinc oxide is deposited by LPCVD or by sputtering. In this step the zinc oxide is also textured by reactive ion etching. In step 4 the zinc oxide front contact is laser scribed using a Nd:YVO₄ laser while the glass is maintained at about 200° C. and a pressure of about 2 Torr. For this laser-scribing step, the laser mechanism is protected from the environment of the chamber where the laser scribing is taking place. Preferably the laser is operated from outside of the chamber whereby the laser light passes through a window in the chamber, the window preferably being made of quartz. In order to protect the window from being coated with the vaporized zinc oxide a sweep gas is passed over the surface of the window that is inside the chamber. Alternatively, a condenser can be placed near the window to preferentially condense the zinc oxide before it reaches the window surface. In another embodiment, the window can be repeatedly and rapidly changed by sliding or swinging another window in its place without substantial loss of vacuum. With this method, a partially obscured window can be removed, cleaned and replaced without interrupting the process. In step 5 the amorphous silicon p, i and n layers of the photovoltaic device are deposited in sequence on the front contact. This deposition step is accomplished at 200° C. and at a pressure of about 2 Torr. The deposition of the p, i, and n-layers is accomplished using one or more techniques such as electron cyclotron resonant microwaves, hot wire CVD, cascaded arc plasmas, rf hollow cathode, or DC cathodic, in order to form the desired uniform layer of the amorphous silicon on the substrate. Since the p, i and n-layers each have different chemical composition and are generally formed using different compositions of feed materials such as silicon hydride, diborane, methane, and phosphine, it is preferable to isolate the different regions in the deposition process so that feed materials used for the deposition of one layer do not contaminate the feed materials of the other layer. Such isolation is accomplished by one or more suitable techniques. For example, between each deposition region of the process, the gases present are pumped out using vacuum pumps with sufficient pumping to prevent the gases from entering an adjacent deposition region. A buffer region can also be used to separate the different deposition regions and this buffer region can be pumped out as described above or swept with an appropriate inert gas to remove any contaminating gasses. Such a vacuum pumping technique or the buffer region with the vacuum pumping or inert gas sweep can also be used to separate the region where the zinc oxide layers are deposited from the regions where the amorphous silicon layers are deposited.

In step 6 the zinc oxide layer of the back (rear) contact is deposited. The zinc oxide is deposited at about 180° C. and at a pressure of about 2 Torr. The preferred method of depositing this zinc oxide layer is to use reactively sputtered zinc metal, either doped with aluminum or boron, using pulsed power supplied to the cathode to insure uniform cathode properties and uniform deposition. In step 7 of the process the amorphous layers and the zinc oxide layer of the back contact are laser scribed using, preferably, a Nd:YVO₄ laser. These laser scribes, as described above, reach through the zinc oxide layer of the back contact and to the amorphous silicon layers but do not scribe the front contact layer. The arrangement for the laser scribing in this step is the same as described in step 4 whereby the laser and the laser controls are outside of the chamber containing the substrate held at about 200° C. and a pressure of 2 Torr. Similarly as described in step 4 above, the window through which the laser beams or beams enter the chamber should be protected from having the material which is removed during the scribing depositing on and obscuring the path of the laser beam. In step 8 the metal layer, preferably aluminum, is deposited at a temperature of about 100-150° C. and at about 4 milliTorr (0.004) Torr pressure. A rotary magnetron is the preferred source of the aluminum rear contact. The rear metal contact can be annealed. Preferably, the annealing step is conducted at a temperature of about 120 to about 200° C. for about 10 to about 30 minutes. If such a heat annealing step is used in the process of this invention, it is preferably accomplished using an in-line infrared source in cylindrical configuration immediately after the metal deposition step and at the same pressure. In step 9 the rear metal contact layer is scribed at ambient pressures and temperatures to isolate each cell in the photovoltaic device and, if the photovoltaic device is to be made partially transparent by removing portions of the back metal contact by laser scribing or by performing other additional scribing of the rear metal contact, it is accomplished in this step. The scribing is preferably accomplished using a Nd:YVO₄ laser. After the laser scribing, the photovoltaic device is preferably washed, preferably ultrasonically to remove any debris that was formed by the laser scribing of the metal layer. In step 10, a narrow strip of the metal and other layers deposited are removed around the perimeter of the photovoltaic device to “edge-isolate” the photovoltaic device. The strip for the edge isolation is generally placed about 0 to about 20 cm from the edge of the device for most applications. In step 11 the device is tested for power output. If satisfactory, electrical connectors are attached in step 12 so the device can be connected to the system in which it will be used. In step 13, a second panel of glass is sandwiched on to the photovoltaic device preferably using a polymeric material such as EVA between the plates of glass to seal and protect the photovoltaic elements.

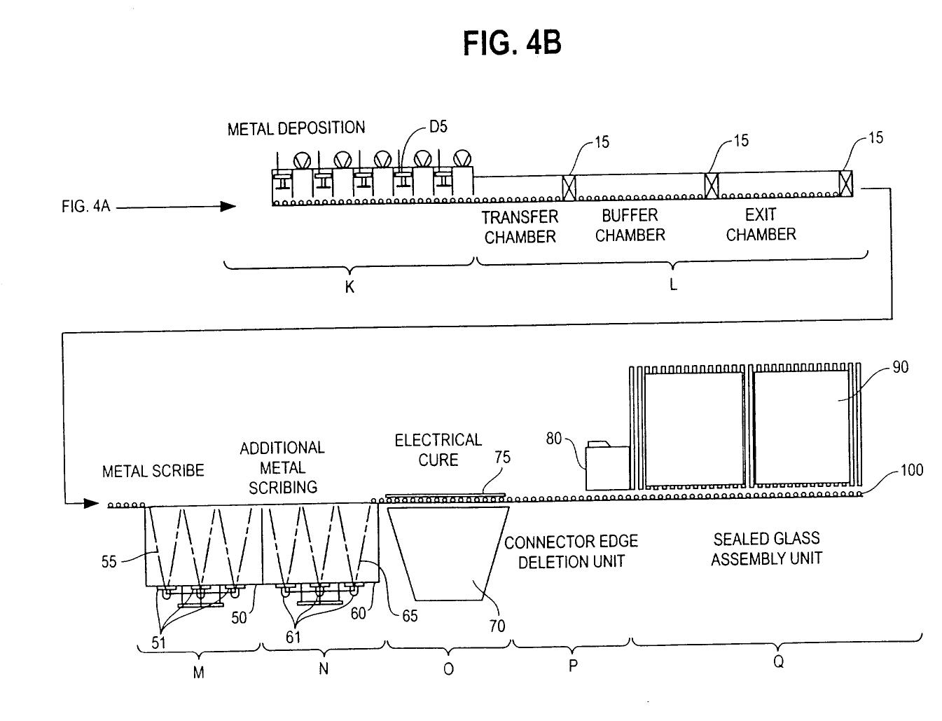

FIG. 4A, which is continued on FIG.4B, shows in schematic form a preferred embodiment of this invention. In this FIG. 4B, section A is a washing station where the glass substrates of various sizes are washed in the glass washer unit shown. Spray washers, with or without brushes 5, assist with the washing of the top side of the substrate glass. Spray washers with or without brushes are also located below the substrate plate to clean the substrate plate but are not shown in the FIG. 4A. In section B, the frit for the electrical connections (i.e., bus bars) is applied and then the glass plate with the frit is heated in a furnace 10 to cure the frit, anneal the glass and raise the glass substrate to the process temperature. Section C is a transition region where the glass substrate is given time to equilibrate in temperature and enter into the evacuated (low pressure) sections of the process. In this transition section C, vacuum pumps are present (not shown in the figure) to provide for and maintain a low pressure. This section also contains a “gate means” such as slit valves 15 which are a means to prevent atmospheric gasses from entering the low-pressure regions and thereby permitting the formation of a vacuum in the low-pressure process areas yet still provide for the passage of the substrate from the atmospheric pressure processing region or part of the process to the reduced pressure section. As shown in FIGS. 4A and 4B the transition section C contains three sections: an entrance chamber, a buffer chamber and a transfer section. In front of the entrance chamber and between each chamber or section in transition section C is positioned a slit valve 15 to provide some degree of isolation between the regions and therefore provide for a more efficient, staged progression from atmospheric to low-pressure regions of the process. A final slit valve or other type of gate means separates the transfer section from the next step in the process. In section D, the front contact made from, for example, zinc oxide is deposited on the substrate using zinc oxide sputtering. Other means for depositing the front contact can be used. As shown in the figure, multiple sources (D1) of the front contact material and multiple vacuum pumps (D2) are employed as the glass substrate moves under the sources and by the pumps. In FIGS. 4A and 4B, all parts depicted in the same manner as D1 represent a means for depositing a material on the substrate, such as zinc oxide or aluminum metal. All parts depicted in the same manner as D2 represent vacuum pumps. The CTO layer may be subsequently etched by reactive ion etching, although not shown in FIGS. 4A and 4B. In section E the CTO front contact is laser scribed using laser and high speed laser scanning unit 20 to form the first scribes in the series of parallel scribes and electrical interconnects which separate the photoelectric device into a series of electrically connected cells. As shown in FIG. 4A, the laser beams 21 are directed from above for this scribing step. One or more Roots blower vacuum pumps D3 or other equivalent means may be used between sections D and E to reduce the transfer of material in the gas phase or in particulate form from section D to section E. Other means for preventing such transfer or contamination can also be used. In FIGS. 4A and 4B, all parts depicted the same as D3 are also Roots blower vacuum pumps or other means to reduce the transfer of gas phase or particulate materials between the regions separated by such gas blowers. In section F an amorphous silicon p-layer is deposited by a dc glow discharge unit 25 such as a pulsed DC PECVD unit. Other means for deposition the amorphous silicon p layer can be used. In section G the intrinsic or i layer of amorphous silicon is deposited by tuned antenna microwave glow discharge units 30, although other means for depositing the amorphous silicon i layer can be used. In section H the amorphous silicon n layer is deposited by a dc glow discharge unit 35 such as a pulsed DC PECVD unit. Other means for deposition the amorphous silicon n layer can be used. In section I the amorphous silicon layers are laser scribed using laser and high speed laser scanning unit 40 to form the grooves or scribes in the amorphous silicon layer for the interconnects between the front contacts and the rear contacts. Laser beams 41 are directed from above in this laser scribing step. In section J the first layer of the rear contact, such as a zinc oxide layer, is deposited by low-pressure vapor deposition units D4. Other means for such deposition can be used. In section K the metal layer, such as aluminum, of the rear contact is deposited by PVD units D5 or other means for depositing a metal rear contact or back contact layer. In section L the photovoltaic device is cooled and the pressure increased to ambient. This section also has “gate means” 15 such as slit valves to separate the low pressure section from the atmospheric pressure section. Section L is shown as having a transfer chamber, a buffer chamber and an exit chamber. Each chamber being separated by the gate means such as slit valves 15 or other means for separating a low pressure section or region from a higher pressure section or region and still permit the passage of the substrate between such sections or regions. In section M the back contact layer of the photovoltaic device having the zinc oxide and metal layers is again subjected to laser scribing using laser scribing unit 50 shown having three scanning laser units 51 to complete the formation of the scribe lines that separate the device into a series of individual series connected cells. In section N optional laser scribing is accomplished using laser scribing unit 60 shown having three scanning laser units 61 if a partially transparent photovoltaic device is desired or if a pattern on the photovoltaic device is desired as described, for example, in U.S. patent application Ser. No. 09/891,752 and in PCT Patent Application PCT/US 01/20398, both of which are incorporated herein by reference. To make a module partially or semi-transparent, additional laser scribes through the metal rear or back contact layer are made across the module preferably perpendicular to the direction of the scribes separating the back contact into individual cells. The number and width of the scribes will determines the degree of semi-transparency the module as described in more detail in U.S. patent application Ser. No. 09/891,752 and in PCT Patent Application PCT/US 01/20398. As shown in FIG. 4B the scribing in sections M and N by laser beams 55 and 65 is accomplished from beneath the substrate, that is, the laser beam enters from the front of the module. During this part of the process, the substrate being scribed is held by a means for supporting the substrate such as a frame or a glass plate (not shown in FIG. 4B) and is moved past the laser beam to permit the laser beams 55 and 65 to impinge upon the substrate and layers to be scribed. In section O the photovoltaic device is subjected to a reverse bias electrical shunting using reverse bias shunting unit 70 to electrically cure any defects in the device. Section O shows subtsrate plate 75 being electrically cured. In section P, the photovoltaic device is edge-scribed, typically using a mechanical abrasion means, such as a grinder, and an electrical connector is added. In section Q the device is sealed with another piece of substrate material such as glass to form the completed, sealed photovoltaic device using sealing unit 90. In such sealing unit, the substrate can be sealed to a second sheet of substrate material by positioning a sheet or layer of sealant material such as poly ethylene vinyl acetate between the sheets and heating the assembly to soften or melt the sealant material and then pressing the sheets together to form the seal. Alternatively, the substrate sheet can be sealed to a second sheet of substrate material using an edge seal and leaving a space between the sheets.

As shown in FIGS. 4A and 4B, each deposition unit D1, 25, 30, 35 and D4 has a pipe or other conduit means, represented as pipe 105 in deposition unit D1 and represented similarly in FIGS. 4A and 4B, for the other deposition units to provide for the introduction of process gas used for the deposition taking place with the respective deposition unit. Also, each section of the process D through K is separated into one or more smaller chambers or sub-chambers by preferably solid, gas impermeable walls or partitions, as represented by 110 in FIG. 4A and represented similarly throughout FIGS. 4A and 4B. As shown in the FIGS. 4A and 4B, the partitions 110 extend down from the top of the low pressure chamber to close proximity to the where the substrate passes the bottom of the partition, for example, a distance below the substrate and the bottom of the partition by, for example, about one millimeter or less. The walls or partitions preferably extend down to provide the minimum distance required for the substrate to pass beneath the lower or bottom end of the wall or partition. These walls or partitions divide each main process section, for example the process sections used to form the CTO layer, D, the amorphous silicon p layer, F, the amorphous silicon i layer, 30, the amorphous silicon n layer, 35, the CTO layer for the back contact, J, and the metal back contact, K, into multiple chambers or sub-chambers as shown, where each sub-chamber contains a deposition unit, a vacuum pump, a blower vacuum pump, or laser scribing process step, as shown in FIGS. 4A and 4B. One such sub-chamber is shown as 112 in FIG. 4A. These sub-chambers provide for the ability to isolate and control the atmosphere or gas composition within each sub-chamber and thereby prevent or inhibit the atmosphere or gas composition present in one sub-chamber from entering and contaminating the adjacent sub-chamber. For each deposition section, the number of sub-chambers can be about 1 to about 20, more preferably about 2 to about 20. Although shown as wall 110 in FIGS. 4A and 4B, the partitions can be any form or device that separates the process unit into separate chambers or sub-chambers. In the preferred apparatus of this invention the different semiconductor layer deposition areas or sections are separated from each other by a combination of sub-chambers containing blower vacuum pumps and vacuum pumps, as shown in FIGS. 4A and 4B. In the preferred apparatus, a sub-chamber containing the Roots blower vacuum pump is positioned between two sub-chambers containing vacuum pumps. In this arrangement, a suitable inert gas purge, which could be nitrogen or other inert gas, is injected into the sub-chamber containing the Roots blower vacuum pump on, for example, each side of the blower vacuum pump, and the purge gas is pumped out or exhausted at a high rate by the blower vacuum pump. Such an arrangement, as shown in FIGS. 4A and 4B between the CTO deposition section D and silicon p-layer section F, between the three silicon deposition sections F, G and H, and between silicon n-layer deposition section H and zinc oxide deposition section J, provides for a reduction in contamination between the individual deposition sections by establishing a diffusion barrier between each deposition section.

In an alternative to the process just described, it may be desirable to make or otherwise obtain pre-manufactured glass substrate having the bus bars positioned on the substrate in the desired configuration. Preferably, such a pre-manufactured glass substrate would comprise a heat tempered or heat strengthened glass substrate. The heat strengthening or heat tempering improves the properties of the glass substrate particularly where the photovoltaic module made therefrom is to be used in an architectural application. Such a pre-manufactured substrate could also be purchased already having deposited thereon a front contact, either textured or untextured in the desired morphology. If heat tempered or heat strengthened glass is used without first having the bus bars positioned thereon, the heating of the substrate to the temperatures necessary to cure the bus bar frit material would likely eliminate the beneficial effect of heat tempering or heat strengthening.

As shown in FIGS. 4A and 4B, the entire process is continuous once the glass substrate of the desired dimensions is loaded onto the conveyor means at the beginning of the process which carries or transports the substrate through the process sections. The conveying means can be any suitable means for transporting or conveying the glass substrate through the different process sections. Mechanically driven rollers (shown as 100 in FIGS. 4A and 4B.) made from an inert and durable materials such as stainless steel, aluminum and fused silica are preferred. All of the chambers or sub-chambers shown in FIGS. 4A-4B in sections C-L and particularly D-K, for example, the chambers or sub-chambers surrounding the various deposition equipment and laser scribing areas, are preferably low-pressure chambers made from a metal or other material to withstand low pressure and elevated temperatures, and designed to establish and maintain the low pressures as described herein that may be used for the various deposition and laser scribing steps described herein. The substrate can move through the process horizontally or vertically or near-vertically (±10°). One of the advantages of the process of this invention is that the laser scribing of the various layers as described herein can be accomplished while the substrate is being moved through the process. In one embodiment of this invention, such laser scribing can be accomplished before the substrate is completely coated with the layer. That is, the laser scribing of a respective layer is accomplished even before the entire layer is applied. In such an embodiment, the laser scribing is preferably located next to or in close proximity to the means used to deposit the layer to be scribed so that, for example, as soon as or very shortly after a region of the substrate passes under or by the source of the layer being deposited, the layer is scribed. Such an arrangement provides for a more compact manufacturing apparatus.

Although this process has been described using a single junction amorphous thin film photovoltaic device, the invention is not limited. The device can be single, double, triple junction. Multiple junction devices having more than three junctions are also possible. In addition, the invention is not limited to amorphous silicon layers. Microcrystalline layers and layers containing materials other than silicon can also be used. If such devices are made by the process of this invention, additional deposition sections can be added. The process of this invention can be adapted easily to such other photovoltaic devices by simply adding another module to accomplish the desired deposition. In the preferred apparatus used in the method of this invention, the different sections used to deposit the desired layers are modular so they can be added or deleted from the apparatus so the overall apparatus can be readily adapted to different configurations of the layers in the photovoltaic devices manufactured. Descriptions of different junction and layers for photovoltaic devices and methods for forming interconnects useful in the process and photovoltaic devices of this invention are described in U.S. Pat. Nos. 6,077,722 and 5,246,506, which are hereby incorporated by reference in their entirety.

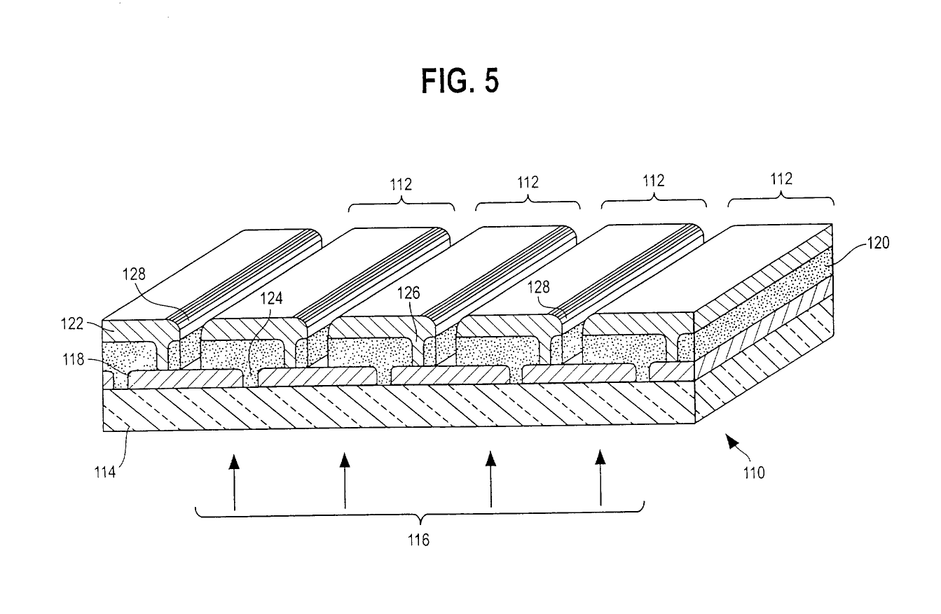

FIG. 5 shows in perspective view a photovoltaic module that can be made by this invention showing how the strips or laser scribes form the individual cells and interconnects in a single junction photovoltaic device. In this FIG. 5, 110 is the photovoltaic device, 112 are the individual cells, 114 is the glass substrate, 116 represents light, 118 is the front, for example zinc oxide contact (silicon dioxide layer is not shown), 120 is the collection amorphous p-i-n junction layers, 122 is the metal back or rear contact (a zinc oxide layer for back content is not shown), 124 is the laser scribe of the front contact filled with amorphous silicon, 126 is the laser scribe through the amorphous silicon filled with metal from the back contact and 128 is the scribe in the back metal contact shown extending through to the front contact.

In the process of this invention, a linear laser beam shape can be used to form the desired scribes, as described hereinabove, in the various layers of a thin film photovoltaic device. Commercially available cylindrical optics or lenses can be used to focus the laser beam in to a linear beam shape. The cylindrical optics can be part of laser beam focusing unit, such as a dynamic focusing unit, or can be a separate unit suitably located prior to a dynamic focusing unit. By linear beam it is meant that the laser beam falling on the substrate surface is in the form of a band having length and width. The length can for example be about 0.01 mm to about 1 meter, more preferably about 10 cm to about 1 meter, and a width, for example, of about 5 microns to about 500 microns, more preferably about 20 microns to about 100 microns. Such a beam can be used to form a desired scribe having the length and width of the beam in a single pulse. Excimer lasers, such as the excimer lasers mentioned above, and preferably a KrF excimer laser operating at 248 nanometers, are preferred when a linear beam shape is desired because they typically have a very high peak power, a short wavelength, a high pulse energy and a short pulse duration. Using a linear shape is advantageous because it can speed up the scribing if the long direction of the beam is-same as scribing direction. Also, when using a linear beam shape the scribe width can be narrowed so that in the finished module more photovoltaically active surface is available for generating electrical energy.

In the process of this invention, the width of the scribe is preferably about the width of the laser beam used to form the scribe. However, the scribe width can be greater if more than one scan is used to make the scribe. In the process of this invention, the average power of the beam focused on and scanned over the substrate to make the scribes in the various layers is suitably about 20 to about 1000 W for scribing the front contact or CTO layers and suitably about 10 to about 20 W for scribing the semiconductor and metal back contact layers. However, it is to be understood that the power of the laser necessary to complete the desired scribes will be a function of such factors as the scribing rate, the laser selected, the size of the laser spot focused on the layer on substrate plate, and the material being scribed.

The high repetition rates for the lasers used in the process of this invention can be obtained by combining laser beams from two or more laser devices, for example, laser cavities. For example, two laser devices, preferably the laser cavities, can be controlled by the same controller where the laser Q-switches for each laser are adjusted so the laser radiation emanating from each laser device are shifted one pulse apart. The repetition rate of the laser beam resulting from such a combination of two laser devices would be twice the repetition rate of each laser, that is, the pulse of a first laser beam comes between the pulses of the second laser beam. In this manner, for example, two laser devices, each operating individually at 100 KHz, can be used to form a laser beam having a repetition rate of 200 KHz. More than two lasers devices can be combined in this manner to achieve even higher repetition rates such as 300 KHz or more, or 400 KHz or more, or 500 KHz or more. In this manner, two laser devices, such as laser cavities, each operating at, for example, 100 KHz and at wavelengths of 1064 nm, can be combined in the manner described above to form a single beam as described above operating at 200 KHz. Such a combined beam can also be passed through a device to increase the frequency of the beam, such as a frequency doubling crystal, to produce a laser beam having a wavelength of 532 nanometers and a repetition rate of 200 KHz.

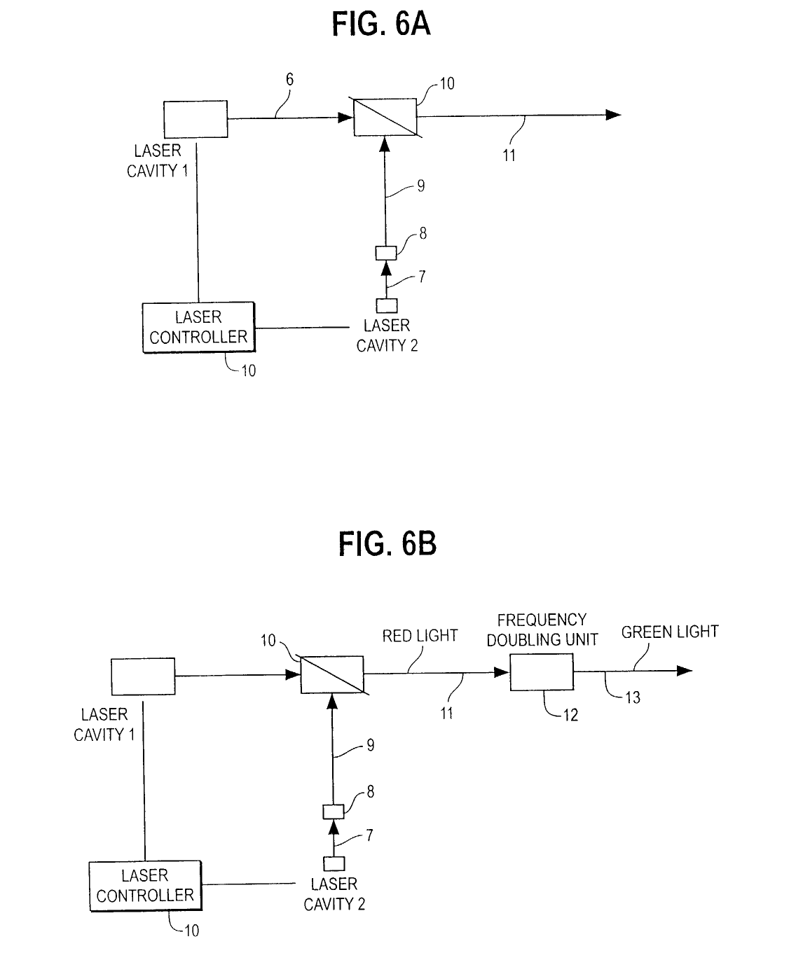

FIG. 6 shows in schematic form two arrangements to produce a high repetition rate laser beam. In FIG. 6A, laser controller 10 controls laser cavity 1 and laser cavity 2 so that the pulses from each laser are one pulse apart. This is typically accomplished by controlling the laser Q-switches in the laser cavities. Laser beam 6 from laser cavity 1 enters laser beam separator/combiner 10. Laser beam 7 from laser cavity 2 enters waveplate 8. Laser beam 9 exits waveplate 8 and enters laser beam separator/combiner 10. Combined laser beam 11 exits laser beam separator/combiner 10 having twice the repetition rate of the laser beams 6 and 9. The waveplate 8 can be used to impart unequal phase shifts to orthogonally polarized field components of the laser beam 7 causing the conversion of one polarization state to another. The laser beam separator/combiner can transmit one polarization state and reflect the other. FIG. 6B is the same as FIG. 6A, with the same components numbered in the same manner, except that the apparatus shown in FIG. 6B also has a frequency doubling unit, for example a frequency doubling crystal, 12, to double the frequency of laser beam 11 to form frequency doubled laser beam 12.

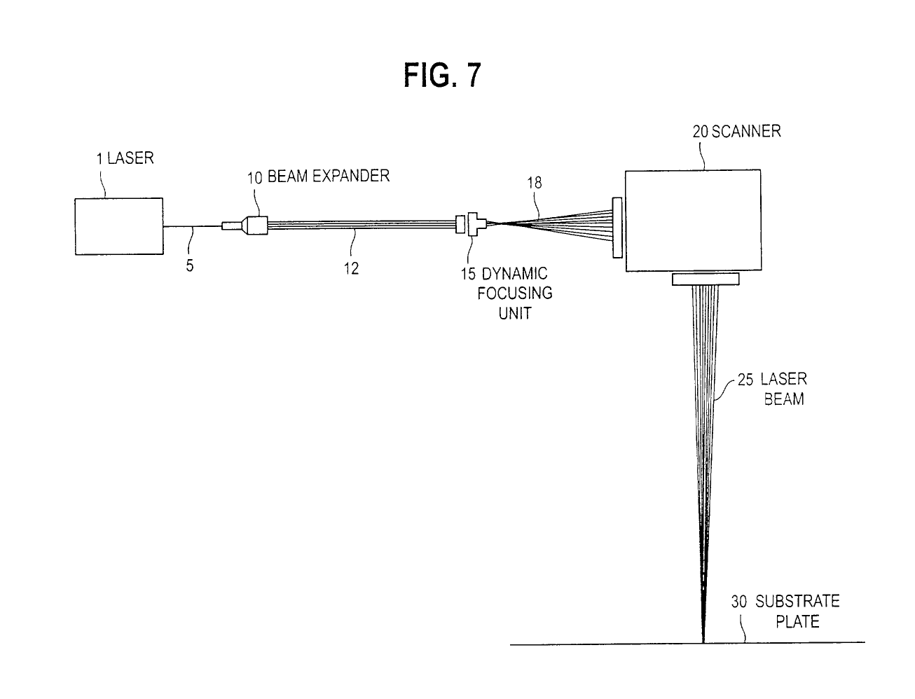

A suitable apparatus for scanning the laser beam across the photovoltaic module to form the grooves, scribes or strips in the front contact, semiconductor layer or layers and in the back contact is shown in FIG. 7. In FIG. 7, laser 1, for example, an excimer laser, such as an ArF (193 nm), KrF (248 nm), XeCl (308 nm), XeF (351 nm), or a solid state laser, for example, an Nd:YAG, Nd:YLF, or Nd:YVO₄ laser, produces laser beam 5 having the desired wavelength and beam shape.

Laser beam 5 enters beam expander 10 to produce expanded laser beam 12. Suitable beam expanders are available from, for example, CVI, Special Optics, OptoSigma, Coherent, and other sources. Beam expander lowers laser beam divergence and generally improves beam quality. Expanded beam 12 enters dynamic focusing unit 15. For very large substrates, for example, substrates having an area of more than about 10 or more than about 15 square feet, the distance between the working surface of the substrate and the laser focusing optics varies as a function of laser beam location on the plate. Dynamic focusing optics or other means for focusing are used to focus the laser beam on the substrate plate during scanning irrespective of the location of the beam on the substrate. A suitable dynamic focusing unit can be obtained from, for example, Scanlab or General Scanning. Using the dynamic focusing unit, the laser beam is focused at the work surface. When the beam is not focused, the energy density is smaller. When the beam is focused into a suitably sized spot, the energy density exceeds ablation threshold of the material to be removed so that the laser scribing can be carried out efficiently. Focused beam 18 exits dynamic focusing unit 15 and enters scanner unit 20. In scanner unit 20 the laser beam is directed to the photovoltaic substrate 30 in the desired pattern to produce scribes in the front contact, the semiconductor layers and in the back metal contact as described hereinabove. The scanner suitably utilizes X-Y coordinate scanning mirrors controlled by galvanometers. The galvanometers are preferably connected electrically to a scanner controller, which is preferably a computer board, which controls the X-Y mirrors and the dynamic focusing unit. The scanner control directs the X and Y mirrors and reflects the beam onto the substrate 30 in the desired pattern. Thus, laser beam 25 exiting the scanner scans rapidly over the surface of the substrate forming the desired scribes or grooves. A galvanometer scanner with two mirrors (X and Y) in an orthogonal configuration is a fast and economical apparatus that can be used to perform the laser scribing in accordance with the process of this invention. Laser scanners, which can be used in the process of this invention, are available from several companies such as General Scanning and Scanlab. Preferably, in the apparatus for carrying out the process of this invention, the laser, dynamic focusing unit and the X-Y scanner are controlled by a common computer which determines when to switch the laser on (a gate control) and where to direct the beam to at a desired focusing condition. A computer such as a commercially available, standard Pentium-type PC computer made by, for example, Hewlett Packard, or equivalent computer, using Microsoft Visual Basic or equivalent control software, is a suitable system for performing the computer controlled operations described herein.

As discussed in detail above, the front contact or the transparent conductive oxide (TCO) layer is preferably scribed first. The scribes are preferably parallel to each other. Photovoltaically active layers such as the amorphous silicon layers are applied to the substrate after the front contact layer. As described above, another set of laser scribes are made preferably parallel to and next to the scribes in the front contact layer. Since the scribes preferably do not cross each other, the second set of scribes is preferably referenced to the scribes in the front contact layer. Several methods can be used in the process of this invention to detect the set of scribes in the front contact layer to set the location and position of the scribes in the photovoltaically active layers (the interconnect scribes) as well as the third set of scribes in the back or rear contact layer. In one method, the scanner is used to scan a low power laser beam, for example a beam produced by lowering the laser diode current. Preferably, the lower power beam also has a very high repetition rate. Low power and high repetition rate are used to reduce laser peak power to minimize and preferably preclude any damage which might otherwise be caused by the scanning laser as it scans the surface of the module. Preferably, the power of the laser is no more than about 10 mW preferably about 1 to about 10 mW. Preferably, the repetition rate is at least about 100 kHz, preferably about 100 to about 1000 kHz. When the low power laser beam passes a scribe in the front contact as it scans the surface of the module, more laser power will pass through the scribe compared to a location on the module without such scribe. The scribe in the front contact reflects and scatters the low power laser beam differently compared to the regions on the module without the scribe. At the edges of the scribes, reflection and scattering of the laser beam are distinctly different from that at other areas. Scribe positions are located by detecting either transmission differences, reflection or scattering of the low power laser beam. Preferably, a camera, such as a CCD (charge coupled device) camera is used to monitor the general area and identify locations where transmission of the low power laser beam is greater or where the laser beam light is scattered or reflected. A telescope may be coupled to the camera so that the process can be monitored at a distance. A fiber optic based camera can be used for flexible handling. Data from the camera is sent to the control computer or other scanner control means and is used to direct the scanner to form the desired scribes. This method of locating the scribes in the front contact is particularly useful for amorphous-silicon based photovoltaic devices when an infrared (IR) laser beam, for example a beam from the fundamental wavelength of a Nd:YAG or other solid state laser as mentioned hereinabove, is used as the low power beam to scan the scribes in the front contact layer because the IR laser beam passes through the amorphous silicon layers and reflects at the front contact layer. When the scanned beam encounters a scribe in the front contact layer most of the beam power is transmitted through the layer and when the beam is on a portion of the front contact layer that is not scribed, most of the beam power is reflected. This difference in the transmitted compared to the reflected beam is used to locate the scribes in the front contact layer and is used as an index to direct the scanner for locating the position of and thereafter forming the scribes in the semiconductor layer and in the back contact layer as described hereinabove. The same laser operating at different power levels and the same scanner can be used to scan for locating the scribe in the front contact layer and for forming the scribes in the amorphous silicon photovoltaically active layers and the back contact layer. In another method, a second, separate scanner and, optionally, a second, separate laser can be used for locating or referencing the scribes in the front contact layer.

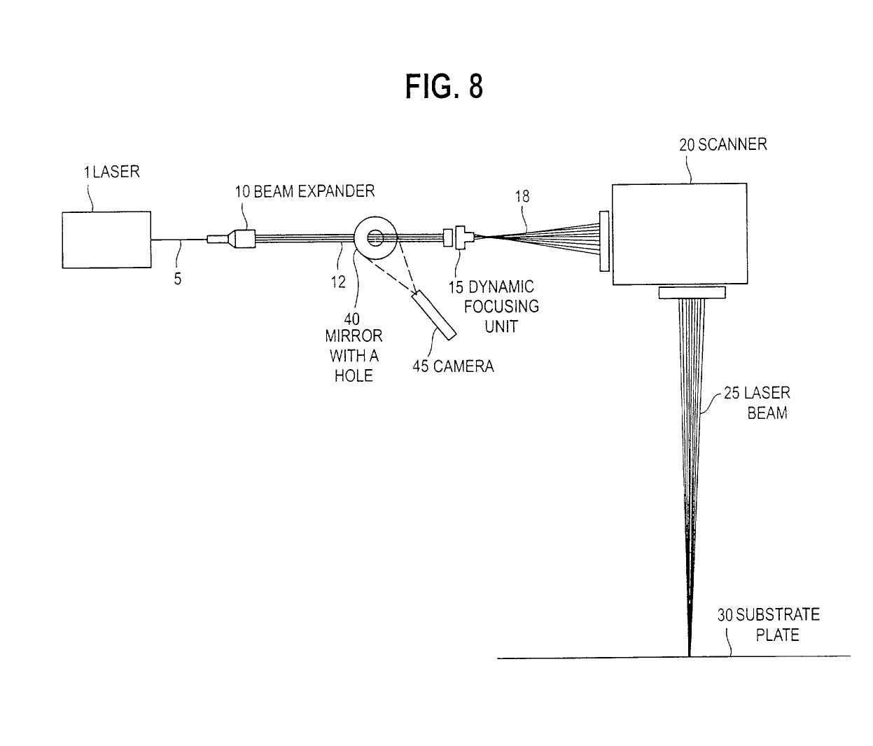

In yet another method, a camera system, such as a CCD camera, can be used to detect the scribe positions in the front contact layer. In one embodiment of this method, a mirror with a hole, preferably in its center, can be positioned just before where the laser beam enters the dynamic focusing unit. The mirror allows the laser beam to pass through the hole and reflects the image of the substrate containing the scribes in the front contact layer to the camera. The image of the substrate being scanned is sent from the camera to the control computer. Since the scanning system with the dynamic focusing unit functions like a telescope, the image of the scribes in the front contact layer is apparent when viewed through the dynamic focusing optics. This image and the data derived therefrom are used to position the scribes in the semiconductor layer and in the back contact. FIG. 8 shows the apparatus of FIG. 7 except that FIG. 8 also includes a mirror 40 with having a hole in it so that laser beam 12 can pass through the hole. Camera 45 as shown in FIG. 8 detects the image of the plate 30 and sends the data to a control computer that controls the operation of the laser and scanners so the desired scribes in the layers on substrate plate 30 can be made at precise locations. Components numbered the same in FIGS. 7 and 8 represent the same components.

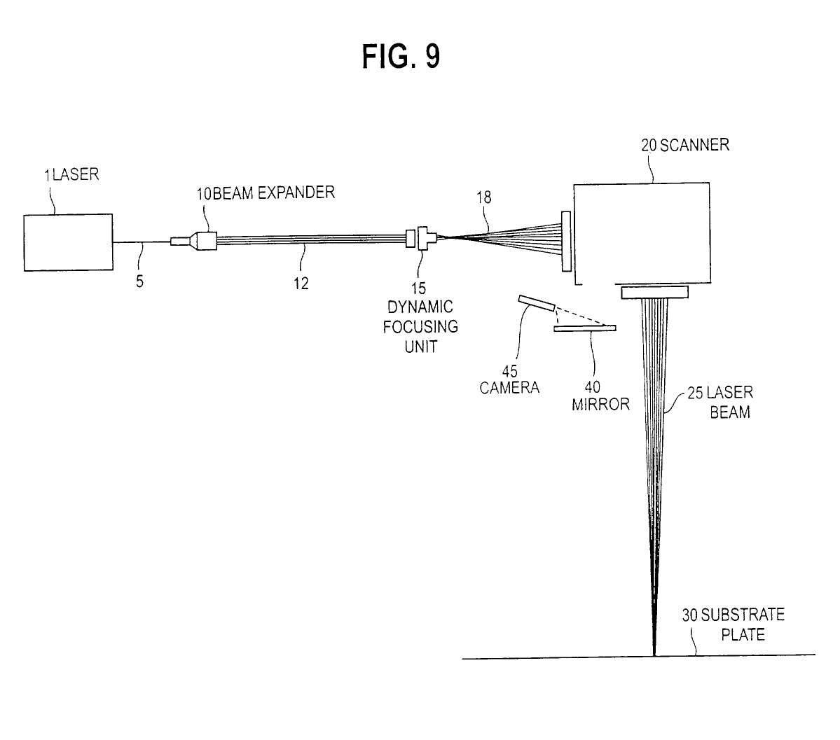

In still another method, the camera, such as a CCD camera, is located after the dynamic focusing unit and positioned to view the X-Y mirror images directly to “see” the scribes in the front contact layer on the substrate. FIG. 9 shows the apparatus of FIG. 7 except that FIG. 9 also includes a mirror 40 and a camera 45 with the camera and mirror positioned to view the X-Y mirrors (not shown) within the scanner. With this apparatus camera 45 detects the image of the plate 30 and sends the data to a control computer that controls the operation of the laser and scanners so the desired scribes in the layers on substrate plate 30 can be made at precise locations. Components numbered the same in FIGS. 7 and 9 represent the same components. In an alternate embodiment, the mirror 40 is not used and camera 45 views the X-Y mirrors in the scanner directly. If linear beams are desired for scribing, linear beam optics can be included in the dynamic focusing unit 15 in FIGS. 7-9 or such optics can be separate and suitably located between beam expander 10 and focusing unit 15 in FIGS. 7-9.

In the process of this invention, a single laser and single scanner can be used to form one or more of the different types of scribes described herein. However, the invention is not so limited. Two or more lasers can be used and two or more scanners can be used to form the desired scribes.

In another embodiment of this invention, or as a separate invention, the interconnect scribe and interconnect through a semiconductor layer can be made in a single step rather then first forming the scribe through the semiconductor layers followed by filling such scribe with the metal of the back contact. In this single step method, the back contact layer is added over the semiconductor layer without scribing the semiconductor layer to form the scribe for the interconnect. The metal layer is subsequently scribed using, for example, a long wavelength laser, such as a solid state laser as described hereinabove, preferably producing laser light having a wavelength of about 1064 nm, and melting the metal layer in the desired locations on the substrate so that the molten metal diffuses through the semiconductor layer to make contact with the front contact located below the semiconductor layer. The scribe rates, scribe widths, pulse rates, repetition rate are as set forth hereinabove for forming the interconnect scribes and the scribes in the back contact layers.

In another embodiment of the present invention, or as a separate invention, scribes in a semiconductor layer, the interconnect and scribes in the back contact are accomplished simultaneously. A method for such simultaneous scribing of the interconnect scribes, making the interconnnect and the scribes in the back contact comprises using two laser beams, preferably of different wavelength light, and separated by a fixed distance corresponding to the distance between the two desired scribes as described hereinabove. The double beam is focused and then directed by the scanning unit to form the scribe in the semiconductor layer or layers and the back contact layer at the same time. In another embodiment for simultaneously forming the scribes in the semiconductor layers and the scribes in the back contact, a laser is used that produces two beams, each of different wavelengths. For example, a Nd:YVO₄ laser producing laser light beams at both 1064 nm (infrared light) and 532 nm (green light). Such a laser is available from, for example, Photonics Industries. A beam displacement optics unit is used to separate the beams into two distinct beams separated by the desired distance determined by a distance desired between the scribes in the semiconductor layers and the scribes in the metal contact layer on the photovoltaic module. Beam displacement optics can be located prior to, after, or as part of the dynamic focusing unit shown in FIGS. 7-9. The appropriately displaced beams of different wavelengths are scanned over the surface of the module using a scanner, as described above. Such a method precludes the scribes from crossing each other because the beams are always side-by-side. Preferably, since the beams are of different wavelengths, broadband optics are used to direct the beams through a single dynamic focusing unit before the beams enter the scanner. In the method for simultaneously forming interconnects and the scribe in the back contact, the interconnect is made by melting the metal layer through the semiconductor layer as described above. The apparatus shown in FIGS. 7-9 can be used to make the interconnect and interconnect scribe at the same time and can also be used to perform the simultaneous scribing of the interconnect and the scribe in the back contact layer.

Methods for scribing the various CTO, amorphous silicon, zinc oxide and metal back contact layers suitable for use in the process of this invention are described in U.S. Provisional Patent Application Serial No. 60/346,327 filed on Jan. 7, 2002, which is incorporated herein by reference in its entirety.

The semiconductor layers, such as the amorphous silicon semiconductor layers, made by the process of this invention where the layers are formed by the substrate moving past a source or sources of the material being deposited, and the photovoltaic devices made from such semiconductor layers are useful for converting light energy into electrical energy, are novel. The semiconductor layers of this invention, such as the amorphous silicon layers, when analyzed for elemental composition proceeding through the depth of the layer exhibit a characteristic oscillating pattern of impurity levels, such as the levels of oxygen, carbon and nitrogen, which are incorporated in the layers during the deposition process. Using as an example the deposition of an amorphous silicon layer, and where the amorphous silicon layer is deposited by moving the substrate past multiple sources of amorphous silicon to deposit the desired layer of amorphous silicon, elemental analysis through the depth of the resulting layer exhibit an oscillation of the concentration of impurities such as one or more of oxygen, nitrogen and carbon, proceeding through the depth of the layer. Oxygen, nitrogen and carbon are natural background elements present in high vacuum chambers and the amount of these impurities deposited on a specific region of the substrate, relative to the amorphous silicon deposited, increases when the region of the substrate is between the sources of the amorphous silicon and decreases when the region of the substrate is under a source of amorphous silicon. The flux of the silicon atoms being deposited, relative to the amount of impurities being deposited, is less between the sources and greater when under the sources. Consequently, the profile of the impurity levels, such as the profile of the concentration of oxygen atoms through the depth of the layer, shows an oscillation of the impurity level with a frequency proportional to the substrate transport rate past the sources of the material being deposited. The number of oscillations will be equal to the number of sources of the material deposited. The semiconductor layers can be analyzed for concentrations of impurities such as oxygen, nitrogen or carbon by one or more standard analytical techniques for elemental analysis such as, for example, Secondary Ion Mass Spectroscopy, Auger Electron Spectroscopy or X-ray Electron Spectroscopy.

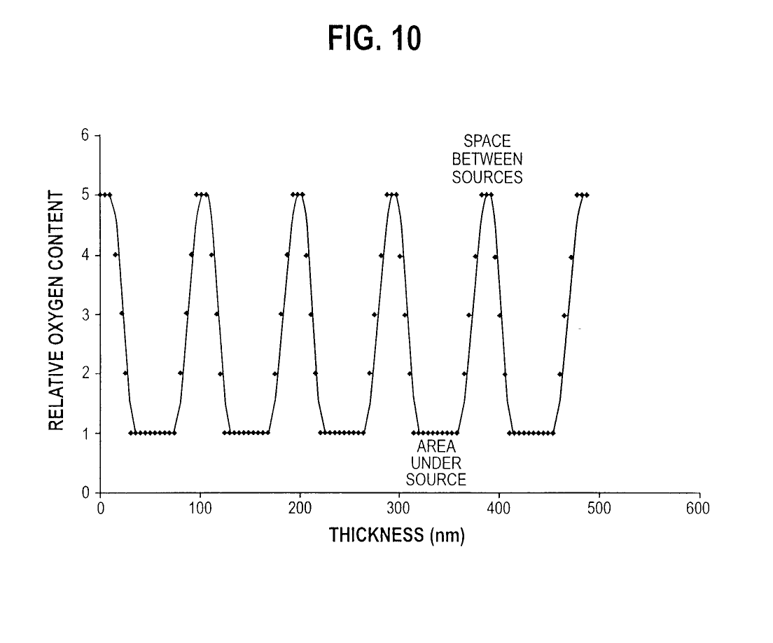

FIG. 10 shows a graphical representation of the relative oxygen content of an amorphous silicon layer of this invention analyzed through the depth or thickness of the layer. As shown in FIG. 10, the relative concentration of oxygen impurity (relative to amorphous silicon) oscillates as the analysis proceeds through the approximately 500 nm depth of the layer from a high of 5 when the amorphous silicon is being deposited at a location on the substrate when that location is between the sources of silicon, to a low of 1 when the silicon is being deposited on the same location when that location is under or next to a source of silicon being deposited. Thus, this invention is a semiconductor layer, particularly an amorphous silicon semiconductor layer, and photovoltaic devices comprising such semiconductor layer or layers, where the concentration of impurities such as, for example, one or more of oxygen, nitrogen or carbon in the layer varies as a function of the depth of the layer. More preferably, where the relative concentration of impurities in the layer or layers oscillates as a function of the depth of the layer relative to silicon, and most preferably where the number of oscillations of the relative concentration of impurities is equal to the number of sources used to deposit the layer.

As mentioned above, the photovoltaic devices of this invention are useful in architectural applications and function as and are used to construct facades or sides of buildings, and in the construction of roofs, canopies, and the like. Thus, this invention is also buildings and other architectural structures, roofs, shades, awnings and canopies constructed, containing or using the photovoltaic devices of this invention particularly where such building, roof, shade, awning or canopy is constructed using large size photovoltaic devices, such as photovoltaic modules, of this invention. Particularly where the size of such photovoltaic devices are at least about 10 square feet, more preferably at least about 15 square feet and more preferably at least about 20 square feet.

U.S. patent application Ser. No. 10/068,733, filed on Feb. 6, 2002, is hereby incorporated by reference in its entirety.

Only certain embodiments of the invention have been set forth and alternative embodiments and various modifications will be apparent from the above description to those of skill in the art. These and other alternatives are considered equivalents and within the spirit and scope of the invention.

That which is claimed is:

1. A process for making a photovoltaic device comprising depositing at least one thin film layer on a substrate using one or more sources of material to be deposited, whereby the substrate and a means for depositing the material move in opposite relation to each other thereby forming on the substrate at least one thin film of the material.

2. The process of claim 1 wherein the material deposited comprises one or more of a transparent conductive oxide, amorphous silicon or a metal.

3. The process of claim 1 wherein the process is a continuous process.

4. The process of claim 1 wherein the process is a semi-continuous process.

5. The process of claim 1 comprising the steps of depositing a layer comprising a transparent conductive oxide layer, depositing at least one layer comprising amorphous silicon and depositing at least one layer comprising a metal, and wherein all the layers are deposited at a relatively similar elevated temperature and a relatively similar reduced pressure.

6. The process of claim 5 wherein the depositing steps are accomplished wherein there is no more than about a 20° C. difference in temperature between each step.

7. The process of claim 6 wherein as between two sequential deposition steps the pressure surrounding the substrate does not vary by more than about 10 Torr between each step.

8. The process of claim 1 further comprising laser scribing at least one layer.

9. The process of claim 5 further comprising laser scribing at least one layer.

10. The process of claim 9 wherein the laser scribing is conducted at about the same pressure and at about the same temperature used to deposit the layer scribed.

11. A process for making a photovoltaic device comprising (a) depositing a CTO layer on a substrate by moving the substrate past one or more sources of the CTO layer, (b) scribing the CTO layer, (c) depositing an amorphous silicon layer on the substrate by moving the substrate past one or more sources of the amorphous silicon; (d) scribing the amorphous silicon layer; and (e) depositing a metal layer on the substrate by moving the substrate past one or more sources of the metal layer and (f) laser scribing the metal layer, where each of the steps (a) through (e) are conducted at or about the same pressure.

12. The process of claim 11 wherein each of steps (a) through (e) are conducted at or about the same temperature.

13. An apparatus suitable for manufacturing a semiconductor layer comprising a means for transporting a substrate; at least one deposition chamber for maintaining a pressure below atmospheric pressure; a means for continuously depositing a semiconductor layer on a substrate as a substrate and the means for depositing the semiconductor layer move in opposite relation to each other.

14. The apparatus of claim 13 further comprising a means for depositing a metal layer on a substrate as a substrate and the means for depositing the metal layer move in opposite relation to each other.

15. An apparatus for depositing at least one layer on a substrate to form a photovoltaic device comprising: a means for transporting the substrate, at least one deposition chamber, a means for depositing photovoltaically active layers on the substrate, means for depositing a front contact layer on the substrate, means for depositing a back contact layer on the substrate, wherein at least one of the depositing means can accomplish the deposition in a continuous manner as the substrate passes the depositing means.

16. The apparatus of claim 15 further comprising at least one laser for scribing at least one layer.

17. The apparatus of claim 16 further comprising a laser scribing chamber and wherein at least one laser is positioned outside the chamber and the chamber having a window to permit the passage of laser light beams into the chamber.

18. The apparatus of claim 15 wherein at least one of the depositing means is stationary.

19. The apparatus of claim 16 further comprising at least one laser scanner.

20. The apparatus of claim 15 wherein the deposition chamber is a low-pressure deposition chamber.

21. A photovoltaic device formed by depositing one or more layers on a substrate wherein at least one of the layers is deposited in a continuous manner as the substrate and means for depositing the layer move in opposite relation to each other.

22. The photovoltaic device of claim 21 comprising at least one amorphous silicon layer.

23. The photovoltaic device of claim 22 comprising at least one p-i-n junction.

24. A semiconductor layer having an oscillating level of impurities through at least a portion of the depth of the layer.

25. The semiconductor layer of claim 24 that is photovoltaically active.

26. A photovoltaic device comprising a semiconductor layer of claim 24.

27. A building facade comprising the photovoltaic devices of claim 21.
